(19) United States
(12) Patent Application Publication
(10) Pub. No.: US 2015/0325689 A1
(43) Pub. Date: Nov. 12, 2015

(54) III-V TRANSISTOR AND METHOD FOR MANUFACTURING SAME

(71) Applicant: Seoul Semiconductor Co., Ltd., Ansan-si (KR)

(72) Inventors: Motonobu TAKEYA, Ansan-si (KR); Kang Nyung LEE, Ansan-si (KR); Kwan Hyun LEE, Ansan-si (KR); II Kyung SUH, Ansan-si (KR); Young Do JONG, Ansan-si (KR); June Sik KWAK, Ansan-si (KR); Yu Dae HAN, Ansan-si (KR)

(73) Assignee: Seoul Semiconductor Co., Ltd., Ansan-si (KR)

(21) Appl. No.: 14/411,344

(22) PCT Filed: Jun. 18, 2013
(86) PCT No.: PCT/KR2013/005334

§ 371 Date: Dec. 24, 2014

(30) Foreign Application Priority Data
Jun. 25, 2012 (KR) 10-2012-0067867
Jul. 20, 2012 (KR) 10-2012-0079277
Jul. 20, 2012 (KR) 10-2012-0079278
Aug. 27, 2012 (KR) 10-2012-0093586

(51) Int. Cl. H01L 29/778; H01L 29/205; H01L 29/10; H01L 29/66; H01L 29/04; H01L 29/423; H01L 21/02; H01L 21/306; H01L 29/20; H01L 29/08

(52) U.S. Cl. CPC H01L 29/7783; H01L 29/2003; H01L 29/205; H01L 29/1037; H01L 29/0847; H01L 29/7788; H01L 29/045; H01L 29/4232; H01L 21/0254; H01L 21/02458; H01L 21/02496; H01L 21/30612; H01L 29/66462

(57) ABSTRACT

Disclosed are a group III-V based transistor and a method for manufacturing same. The group III-V based transistor includes a laminated semiconductor structure having an upper surface and a lower surface and including a group III-V based semiconductor layer, and at least one 2DEG region extending from the upper surface of the laminated semiconductor structure to the lower surface thereof. A vertical-type GaN-based transistor using 2DEG can be provided by adopting the 2DEG region.

### CROSS-REFERENCE TO RELATED APPLICATIONS

This application is the National Stage Entry of International Application PCT/KR2013/005334, filed on Jun. 18, 2013, and claims priority from and the benefit of Korean Patent Application No. 10-2012-0067867, filed on Jun. 25, 2012, Korean Patent Application No. 10-2012-0079277, filed on Jul. 20, 2012, Korean Patent Application No. 10-2012-0079278, filed on Jul. 20, 2012, and Korean Patent Application No. 10-2012-0093586, filed on Aug. 27, 2012, all of which are incorporated herein by reference for all purposes as if fully set forth herein.

### BACKGROUND

1. Field

The present invention relates to a transistor used in power devices, and more particularly, to a group III-V based transistor, such as a gallium nitride-based transistor, and a method of fabricating the same.

2. Discussion of the Background

A power device using a silicon semiconductor is used in a power amplification circuit, a power source circuit, a motor drive circuit, and the like. However, a limit of the silicon semiconductor provides constraints on achievement of high withstand voltage, low resistance and rapid switching of silicon devices, thereby making it difficult to satisfy market demand. Particularly, the silicon semiconductor has low insulation breakdown strength and is thus required to have a considerably large size in order to operate at high voltage. Accordingly, there is a need for development of III-V devices which have characteristics such as high withstand voltage, operation at high temperature, high current density, rapid switching, and low on-resistance.

On the other hand, a heterojunction field effect transistor (HFET) using a heterojunction of GaAs/AlGaAs has very high electron mobility and is thus used as a rapid switching device. However, the GaAs/AlGaAs-based HFET also has very low insulation breakdown strength and thus exhibits negative withstand voltage characteristics. An InP/InGaAs-based HFET also exhibits negative withstand voltage characteristics.

The HFET using a heterojunction of GaAs/AlGaAs can secure high saturation electron velocity and high electron mobility through 2DEG regions by polarization voltage, and also has very high insulation breakdown strength, thereby providing high withstand voltage characteristics.

However, such group III-V based devices suggested as above have a lateral structure in which a source, a gate and a drain are arranged along a substrate surface, and thus are not suited to power devices which require large current. Moreover, GaN devices have a difficulty in normally off operation essential for power devices. In addition, the GaN power devices suffer from severe current leakage at a gate electrode and a so-called current collapse phenomenon in which electrons are caught between the semiconductor layer and a protective layer upon operation at high voltage, thereby causing reduction in drain current. Furthermore, a lateral type III-V device, particularly, a GaN device, has insufficient withstand voltage and is thus used for application to rapid response of 600V or less.

To solve the problem of the lateral type device, a vertical type GaN device has been suggested in the art (see Japanese Patent Laid-open Publication No. 2008-53450). The vertical type GaN device is formed by forming a gate channel area composed of n−/p+/n− semiconductor layers, dry etching the semiconductor layers to form a recess in the gate channel area, and forming a gate insulation layer and a gate in the recess.

However, in the course of dry etching the semiconductor layers, the semiconductor surface is damaged by plasma, thereby making it difficult to obtain good channel characteristics. Such etching damage traps carriers, thereby having a negative influence on channel characteristics. Although wet etching may be additionally performed to remove etching damage on the semiconductor surface, it is difficult to achieve complete removal of etching damage by plasma.

Moreover, the vertical type GaN device does not use two-dimensional electron gas (2DEG) and is thus difficult to operate at rapid speed.

### SUMMARY

It is an aspect of the present invention to provide a vertical type group III-V based transistor, particularly, a gallium nitride transistor, which employs two-dimensional electron gas (2DEG).

It is another aspect of the present invention to provide a vertical type group III-V based transistor, particularly, a gallium nitride transistor, which can prevent etching damage by plasma.

It is a further aspect of the present invention to provide a gallium nitride transistor, which can prevent deterioration in channel characteristics due to etching damage by plasma.

It is yet another aspect of the present invention to provide a vertical type group III-V based transistor, particularly, a gallium nitride transistor, which has a high withstand voltage of 600 V or higher.

It is yet another aspect of the present invention to provide a gallium nitride transistor, which can overcome problems of gate current leakage and current collapse.

It is yet another aspect of the present invention to provide a transistor having high current density, rapid switching, and low on-resistance.

In accordance with one aspect of the present invention, a group III-V based transistor includes: a semiconductor stack having an upper surface and a lower surface and including a III-V based semiconductor layer; and at least one 2DEG region extending from the upper surface of the semiconductor stack to the lower surface thereof.

By adopting the 2DEG region, it is possible to provide a vertical type group III-V based transistor using 2DEG while enhancing withstand voltage characteristics through thickness adjustment of the semiconductor stack.

In addition, the group III-V based transistor may further include: a source electrode disposed on the upper surface of the semiconductor stack and connected to a first III-V based semiconductor layer; a gate electrode disposed between the first III-V based semiconductor layer and the 2DEG region to form a channel therebetween; and a drain electrode disposed on the lower surface of the semiconductor stack.

The group III-V based transistor may further include a support substrate. Here, the drain electrode may be disposed between the support substrate and the semiconductor stack. The drain electrode may be connected to the 2DEG region.

In some embodiments, the group III-V based transistor may further include an insulation layer disposed within a region between the source electrode and the first III-V based semiconductor layer. The insulation layer may be disposed on a dislocation defect area of the semiconductor stack to prevent current leakage.

In some embodiments, the group III-V based transistor may further include a current spreading layer disposed on the upper surface of the semiconductor stack and connected to the 2DEG region. The current spreading layer disperses carriers to a plurality of 2DEG regions when the carriers are introduced into the current spreading layer from a source electrode through the channel under the gate electrode when turned on. As a result, the carriers may be transferred to the drain electrode through distribution to the plurality of 2DEG regions, thereby enabling rapid operation.

In addition, the group III-V based transistor may further include an insulation layer disposed within a region between the current spreading layer and the semiconductor stack. The insulation layer may be disposed on the dislocation defect area of the semiconductor stack to prevent current leakage.

The semiconductor stack may include: a first conductive type first III-V based semiconductor layer including an upper surface, a lower surface and a side surface; a first conductive type second III-V based semiconductor layer surrounding the lower surface and the side surface of the first conductive type first III-V based semiconductor layer; a second conductive type III-V based semiconductor layer disposed between the first III-V based semiconductor layer and the second III-V based semiconductor layer and separating the first III-V based semiconductor layer and the second III-V based semiconductor layer from each other; and at least one channel layer disposed near a side surface of the first conductive type second III-V based semiconductor layer and inducing a 2DEG region.

With the second conductive type III-V based semiconductor layer disposed between the first conductive type first III-V based semiconductor layer and the second III-V based semiconductor layer, the transistor may exhibit normally off characteristics.

The source electrode may be electrically connected to the first conductive type first III-V based semiconductor layer, the gate electrode may be disposed to form a channel in the second conductive type III-V based semiconductor layer, and the drain electrode may be disposed on the lower surface of the semiconductor stack.

The source electrode may also be electrically connected to the second conductive type III-V based semiconductor layer. In some embodiments, the first conductive type III-V based semiconductor layer may include a recess exposing the second conductive type III-V based semiconductor layer, and the source electrode may be electrically connected to the second conductive type III-V based semiconductor layer through the recess.

The first conductive type first III-V based semiconductor layer may include a gallium nitride semiconductor layer, and the upper surface of the first conductive type first III-V based semiconductor layer may include an N-face. In addition, at least one of the first conductive type first III-V based semiconductor layer, the second conductive type III-V based semiconductor layer and the first conductive type second III-V based semiconductor layer may include an etched face formed by wet etching.

The side surface of the first conductive type first III-V based semiconductor layer may include a (11-22) face or a (1-101) face. In particular, the side surface of the first conductive type first III-V based semiconductor layer may be determined depending upon a longitudinal direction of a stripe. For example, when the longitudinal direction of the stripe is <1-100>, the side surface of the first III-V based semiconductor layer is a (11-22) face, and when the longitudinal direction of the stripe is <11-20>, the side surface of the first III-V based semiconductor layer is a (1-101) face.

The group III-V based transistor may include a plurality of first channel layers composed of AlInGaN semiconductor layers; and a plurality of second channel layers each being disposed between the first channel layers and composed of AlInGaN semiconductor layers. The 2DEG regions may be formed in the second channel layers by the first channel layers. In addition, the plurality of first channel layers and the plurality of second channel layers may form a superlattice structure. Further, the first channel layers may be formed of AlGaN and the second channel layers may be formed of GaN.

In accordance with another aspect of the present invention, a group III-V based transistor includes: a semiconductor stack having an upper surface and a lower surface and including a III-V based semiconductor layer; and a support substrate disposed on the lower surface of the semiconductor stack. The III-V based semiconductor layer may include a gallium nitride semiconductor layer and the upper surface of the semiconductor stack may include an N-face.

In addition, the semiconductor stack may include an etched face formed by wet etching the N-face, and may include a recess formed on the upper surface thereof.

It is difficult to perform patterning of a Ga-face of the gallium nitride semiconductor layer using wet etching. Thus, patterning is performed by plasma dry etching, thereby causing plasma etching damage to the semiconductor layer. Such etching damage formed on the Ga face is difficult to remove by wet etching. On the contrary, the N-face of the gallium nitride semiconductor layer allows wet etching using KOH, H₃PO₄, NaOH, and the like. Here, since the upper surface of the semiconductor stack opposite to the support substrate includes the N-face, patterning of the semiconductor stack can be achieved by wet etching, thereby preventing plasma etching damage. Furthermore, a portion damaged by plasma can be easily removed by wet etching after patterning the N-face through dry etching.

In accordance with a further aspect of the present invention, a method for manufacturing a group III-V based transistor includes: forming a stripe of a III-V based semiconductor on a growth substrate. A plurality of III-V based semiconductor layers is grown on the stripe, and grown in an upward direction and in a lateral direction of the stripe. Then, a support substrate is attached to the plurality of III-V based semiconductor layers and the growth substrate is separated from the plurality of semiconductor layers.

As a result, a gallium nitride transistor may be manufactured using a stack of semiconductor layers, an upper surface of which includes an N-face, thereby providing a transistor that does not have etching damage.

The operation of growing the plurality of semiconductor layers may include: growing a first conductive type III-V based semiconductor layer on the stripe; growing a second conductive type III-V based semiconductor layer on the first conductive type III-V based semiconductor layer; growing a first conductive type second III-V based semiconductor layer on the second conductive type III-V based semiconductor layer; and growing at least one III-V channel layer on the second III-V based semiconductor layer to form a 2DEG region.

The second conductive type III-V based semiconductor layer may be disposed between the first conductive type III-V based semiconductor layer and the second III-V based semiconductor layer, thereby providing a group III-V based transistor having normally off-characteristics.

In addition, the semiconductor layers are grown on the stripe, whereby the 2DEG regions extending from an upper surface of the semiconductor stack to a lower surface thereof can be formed.

On the other hand, the first conductive type may be n-type and the second conductive type may be p-type. The method may further include activating impurities of the second conductive type III-V based semiconductor layer. The activation may be performed before or after separation of the growth substrate.

A plurality of III-V-based first channel layers and a plurality of III-V-based second channel layers may be alternately grown on the first conductive type second III-V based semiconductor layer. The plurality of first channel layers and the plurality of second channel layers may form a superlattice structure.

The method may further include partially removing an upper surface of the plural semiconductor layers to expose at least one 2DEG region before attaching the support substrate.

In addition, separation of the growth substrate may include separating the growth substrate from the plurality of semiconductor layers using laser lift-off, and wet etching the exposed semiconductor layer. The surface of the semiconductor layer exposed by removing the growth substrate may be an N-face and thus allows patterning via wet etching and may be formed with a recess.

In accordance with yet another aspect of the present invention, a gallium nitride transistor includes: a semiconductor stack having an upper surface and a lower surface and including a gallium nitride semiconductor layer; at least one 2DEG region extending from the upper surface of the semiconductor stack to the lower surface thereof; a source electrode disposed on the upper surface of the semiconductor stack and connected to the semiconductor stack; a gate electrode disposed on the upper surface of the semiconductor stack between the source electrode and the 2DEG region; and a drain electrode disposed on the lower surface of the semiconductor stack and connected to the 2DEG region.

By adopting the 2DEG region, it is possible to provide a vertical type gallium nitride transistor using 2DEG.

In some embodiments, on the lower surface of the semiconductor stack, at least a portion of a lower region of the source electrode does not adjoin the drain electrode. With this structure, the gallium nitride transistor can prevent direct migration of carriers from the source electrode to the drain electrode through the semiconductor stack under the source electrode, thereby securing high withstand voltage characteristics.

The gallium nitride transistor may further include a first current blocking layer adjoining the lower surface of the semiconductor stack, and the first current blocking layer may adjoin a lower region of the source electrode among the lower surface of the semiconductor stack.

At least some of the 2DEG regions may be disposed to have a mirror symmetry structure. In addition, the gallium nitride transistor may further include a second current blocking layer adjoining the lower surface of the semiconductor stack, and the second current blocking layer may contact the lower surface of the semiconductor stack placed at a center of the mirror symmetry structure.

In some embodiments, the gallium nitride transistor may further include a third current blocking layer disposed between the source electrode and the semiconductor stack. In addition, the semiconductor stack has a recess on the upper surface thereof, and at least a portion of the source electrode may be connected to the semiconductor stack within the recess. Here, the third current blocking layer may be disposed within the recess.

The third current blocking layer prevents carriers from flowing from the source electrode to the drain electrode directly through the semiconductor stack, thereby enhancing withstand voltage characteristics of the transistor.

In some embodiments, the gallium nitride transistor may include a current blocking layer. Further, the semiconductor stack may include a first dislocation defect area in which dislocations are concentrated under the source electrode, and the current blocking layer blocks current flow through the first dislocation defect area between the source electrode and the drain electrode.

The current blocking layer may adjoin the lower surface of the semiconductor stack, or may be disposed between the source electrode and the semiconductor stack. Particularly, the semiconductor stack may include a recess and the current blocking layer may be disposed within the recess.

The gallium nitride transistor may further include a current spreading layer disposed on the upper surface of the semiconductor stack and connected to the 2DEG region. In addition, the gallium nitride transistor may further include a current blocking layer. Here, the semiconductor stack may include a second dislocation defect area placed under the current spreading layer, and the current blocking layer may block current block through the second dislocation defect area between the current spreading layer and the drain electrode. The current blocking layer may adjoin the lower surface of the semiconductor stack.

The semiconductor stack may include a first conductive type first gallium nitride semiconductor layer having an upper surface, a lower surface and a side surface; a first conductive type second gallium nitride semiconductor layer surrounding the lower surface and the side surface of the first conductive type first gallium nitride semiconductor layer; a third gallium nitride semiconductor layer disposed between the first gallium nitride semiconductor layer and the second gallium nitride semiconductor layer to separate the first gallium nitride semiconductor layer from the second gallium nitride semiconductor layer; and at least one channel layer disposed near a side surface of the first conductive type second gallium nitride semiconductor layer and forming a 2DEG region.

The source electrode may be electrically connected to the first conductive type first gallium nitride semiconductor layer and the gate electrode may be disposed to form a channel in the third gallium nitride semiconductor layer when turn-on voltage is applied. Furthermore, the source electrode may be electrically connected to the third gallium nitride semiconductor layer.

The third gallium nitride semiconductor layer may include a high resistance (i-type) gallium nitride layer having a wider band-gap than the second conductive type gallium nitride semiconductor layer or the first and second gallium nitride semiconductor layers. Particularly, the first and second gallium nitride semiconductor layers may be n-type GaN layers, and the third gallium nitride semiconductor layer may be a p-type GaN layer or an i-type AlGaN layer. The high resistance (i-type) gallium nitride layer used as the third gallium nitride semiconductor layer allows omission of a process of activating p-type impurities such as Mg, thereby simplifying a manufacturing process.

In addition, the gallium nitride transistor may further include a high resistance (i-type) gallium nitride layer disposed between the channel layer and the second gallium nitride semiconductor layer while surrounding a side surface and a lower surface of the second gallium nitride semiconductor layer.

The upper surface of the semiconductor stack may include an N-face.

In accordance with yet another aspect of the present invention, a nitride transistor includes: a semiconductor stack having an upper surface, a lower surface and an inclined surface extending from the upper surface to the lower surface, and including a nitride semiconductor layer; and a first regrowth layer formed on a partial region of the inclined surface. The first regrowth layer is a nitride semiconductor layer having a different composition from that of a nitride semiconductor layer formed in the partial region of the inclined surface under the first regrowth layer.

The structure of the first regrowth layer formed on the inclined surface of the semiconductor stack may provide a 2DEG region extending from the upper surface of the semiconductor stack to the lower surface thereof, thereby providing a vertical type nitride transistor employing 2DEG.

The nitride transistor may further include a source electrode disposed on the upper surface of the semiconductor stack and connected to a first nitride semiconductor layer; a gate electrode forming a channel between the first nitride semiconductor layer and the first regrowth layer; and a drain electrode connected to the lower surface of the semiconductor stack. Here, at least a portion of the gate electrode forms the channel in a region between the upper surface of the semiconductor stack and the first regrowth layer.

The nitride transistor may further include a support substrate, and the drain electrode may be disposed between the support substrate and the semiconductor stack. In addition, the drain electrode may be connected to the first regrowth layer.

On the other hand, a gate insulation layer may be disposed between the gate electrode and the inclined surface. The structure of the gate electrode disposed on the gate insulation layer can prevent current leakage from the gate electrode.

The nitride transistor may further include a second regrowth layer formed on the first regrowth layer. Here, the second regrowth layer may be a nitride semiconductor layer having a different composition than the composition of the first regrowth layer.

The nitride transistor may include a 2DEG region, which may be formed at an interface between the semiconductor stack and the first regrowth layer or at an interface between the first regrowth layer and the second regrowth layer. It is possible to adjust a location at which the 2DEG region is formed by adjusting the compositions of the semiconductor stack, the first regrowth layer and the second regrowth layer.

On the other hand, the semiconductor stack includes a first nitride semiconductor layer; a second nitride semiconductor layer; and a channel layer disposed between the first nitride semiconductor layer and the second nitride semiconductor layer and composed of a nitride semiconductor layer. Each of the first nitride semiconductor layer, the second nitride semiconductor layer and the channel layer is exposed to the inclined surface, and the first regrowth layer is disposed on a partial layer of the second nitride semiconductor layer.

The nitride transistor may further include a source electrode, a drain electrode, and a gate electrode, in which the source electrode may be electrically connected to the first nitride semiconductor layer, the gate electrode may be disposed to form a channel in the channel layer, and the drain electrode may be disposed on the lower surface of the semiconductor stack.

In addition, the source electrode may be electrically connected to the channel layer.

On the other hand, an upper surface of the first nitride semiconductor layer may include an N-face. Further, the inclined surface of the semiconductor stack may include an etched surface formed by wet etching the N-face.

In accordance with yet another aspect of the present invention, a method for manufacturing a nitride transistor includes: growing a plurality of semiconductor layers including a first nitride semiconductor layer, a channel layer and a second nitride semiconductor layer on a growth substrate; attaching a support substrate to an upper surface of the plurality of semiconductor layers; and removing the growth substrate from the plurality of semiconductor layers. Thereafter, an inclined surface may be formed to expose side surfaces of the first nitride semiconductor layer, the channel layer and the second nitride semiconductor layer by etching the semiconductor layers. In addition, a first regrowth layer may be formed on a partial region of the inclined surface. The first regrowth layer may be formed on the partial region of the inclined surface below the channel layer. The first regrowth layer may be a nitride semiconductor layer having a different composition than that of the second nitride semiconductor layer.

By forming the first regrowth layer on the inclined surface, it is possible to manufacture a vertical type nitride transistor employing the 2DEG region.

On the other hand, a surface of the semiconductor layers from which the growth substrate is removed may include an N-face, and the semiconductor layers may be etched by wet etching or dry and wet etching. Accordingly, it is possible to prevent or remove etching damage by plasma.

The channel layer may be a nitride semiconductor layer having a different conductive type than those of the first nitride semiconductor layer and the second nitride semiconductor layer. Accordingly, this structure can prevent current leakage from the gate electrode.

The nitride transistor manufacturing method may further include forming a second regrowth layer on the first regrowth layer. The second regrowth layer may be a nitride semiconductor layer having a different composition than that of the first regrowth layer.

On the other hand, after the second regrowth layer is formed, a source electrode connected to the first nitride semiconductor layer and a gate electrode forming a channel in the channel layer may be formed.

In addition, the nitride transistor manufacturing method may further include: separating the support substrate from the semiconductor layers, and forming a drain electrode on an exposed surface of the semiconductor layers formed by removal of the support substrate.

In accordance with yet another aspect of the present invention, a hybrid transistor is provided. The hybrid transistor includes a switching element and a channel element electrically connected to the switching element. In addition, the channel element includes a stack of gallium nitride semiconductor layers forming a 2DEG region. In addition, the channel element may form a plurality of 2DEG regions.

According to embodiments of the invention, the nitride transistor has high withstand voltage characteristics using the channel element, thereby allowing further reduction in size of the switching element. Further, the channel element using the stack of the gallium nitride semiconductor layers is used together with a switching element capable of rapid switching, thereby securing high current density, rapid switching, and low on-resistance.

The channel element may include a first electrode connected to one side surface of the stack; and a second electrode connected to the other side of the stack. The first electrode is electrically connected to the switching element.

On the other hand, the switching element may include a source electrode and a drain electrode, and the drain electrode of the switching element may be electrically connected to the first electrode of the channel element.

The hybrid transistor may further include a substrate supporting the switching element and the channel element. That is, the switching element and the channel element are disposed on a common substrate.

The switching element may include any element having a switching function, and particularly, a MOSFET or an HFET, without being limited thereto.

In some embodiments, the substrate may include a Si substrate, and the MOSFET may include a Si-based MOSFET formed on the Si substrate.

In other embodiments, the HFET may include a GaAs/AlGaAs HFET or an InP/InGaAs HFET. More preferably, the switching element is the GaAs/AlGaAs HFET, which allows rapid switching by high electron mobility.

On the other hand, the switching element may be disposed parallel to the channel element on the substrate, but is not limited thereto. Alternatively, the switching element may be disposed on the channel element. This structure can reduce an area occupied by the channel element and the switching element.

In some embodiments, the substrate is a growth substrate for growing the gallium nitride semiconductor layers of the channel element, and the gallium nitride semiconductor layers of the channel element may be attached to the substrate after being grown on the substrate.

In other embodiments, the channel element may be manufactured independently of the substrate and then mounted on the substrate. For example, the substrate may include bonding pads and the channel element may be bonded to the bonding pads on the substrate. On the other hand, the switching element may be electrically connected to one of the bonding pads, whereby the switching element may be electrically connected to the channel element.

According to embodiments of the invention, a group III-V based transistor of a vertical structure using 2DEG, particularly, a gallium nitride transistor, may be provided by adopting 2DEG regions extending from an upper surface of a semiconductor stack to a lower surface thereof, thereby preventing current collapse.

In addition, with the vertical structure, the transistor having high withstand voltage characteristics can be easily manufactured through thickness adjustment of the semiconductor stack. Furthermore, a gallium nitride transistor of a vertical structure having high withstand voltage characteristics may be provided by adopting a current blocking layer for blocking current leakage through a dislocation defect area.

Further, since the transistor is manufactured using an N-face semiconductor layer, it is possible to provide a GaN transistor free from plasma etching damage.

Furthermore, a group III-V based transistor, particularly, a gallium nitride transistor, which has normally off characteristics, may be provided by the structure in which a second conductive type semiconductor layer or a high resistance gallium nitride semiconductor layer having a relatively high band-gap is disposed between first conductive type semiconductor layers. In addition, it is possible to provide a power device having high withstand voltage, low resistance, and rapid switching characteristics using the group III-V based transistor.

On the other hand, a switching element and a channel element are electrically connected to a hybrid transistor such that switching characteristics can be realized by the switching element and withstand voltage characteristics can be realized by the channel element, whereby the hybrid transistor may have high withstand voltage characteristics. In addition, with the switching element capable of rapid switching and the channel element having a plurality of 2DEG regions, the hybrid transistor has high current density, rapid switching, and low on-resistance. Furthermore, since high withstand voltage characteristics of the transistor can be achieved by the channel element, withstand voltage characteristics of the switching element does not have a significant influence on the transistor. Accordingly, the transistor according to the embodiments of the invention may employ a small switching element, particularly, a Si-based MOSFET or a GaAs/AlGaAS or InP/InGaAs-based HFET, which has poor withstand voltage characteristics.

### BRIEF DESCRIPTION OF THE DRAWINGS

FIG. 1 is a schematic sectional view of a group III-V based transistor according to a first embodiment of the present invention.

FIG. 2 is a schematic sectional view of a group III-V based transistor according to a second embodiment of the present invention.

FIG. 3 is a schematic sectional view of a group III-V based transistor according to a third embodiment of the present invention.

FIG. 14 is a schematic sectional view of a group III-V based transistor according to a fourth embodiment of the present invention.

FIG. 15 is a schematic sectional view of a group III-V based transistor according to a fifth embodiment of the present invention.

FIG. 4 to FIG. 13 are sectional views illustrating a method for manufacturing the group III-V based transistor according to the first embodiment of the present invention.

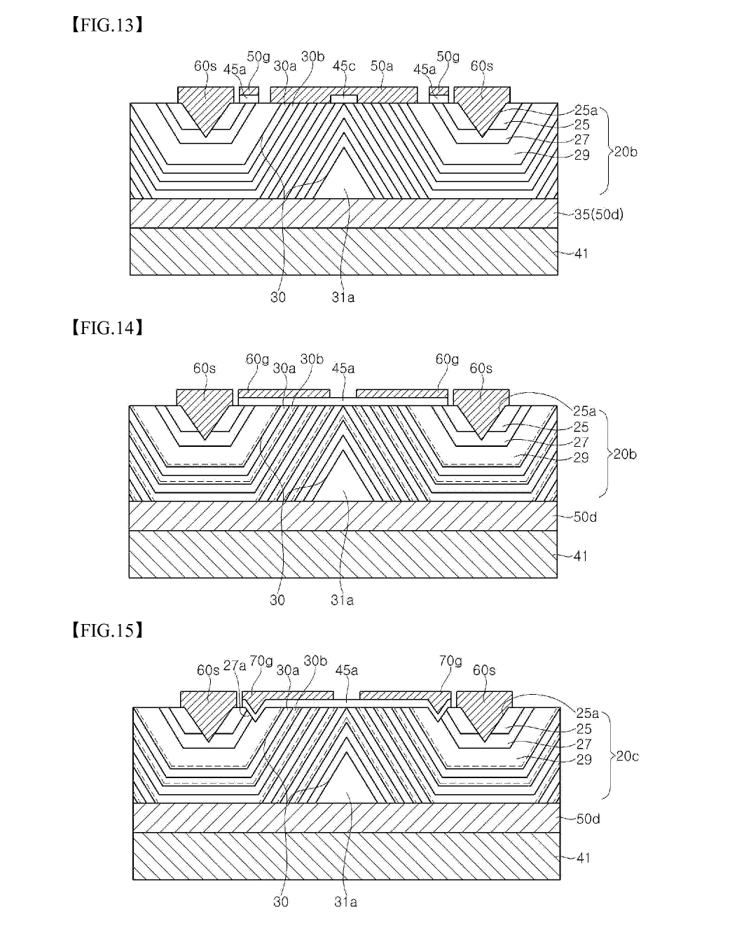

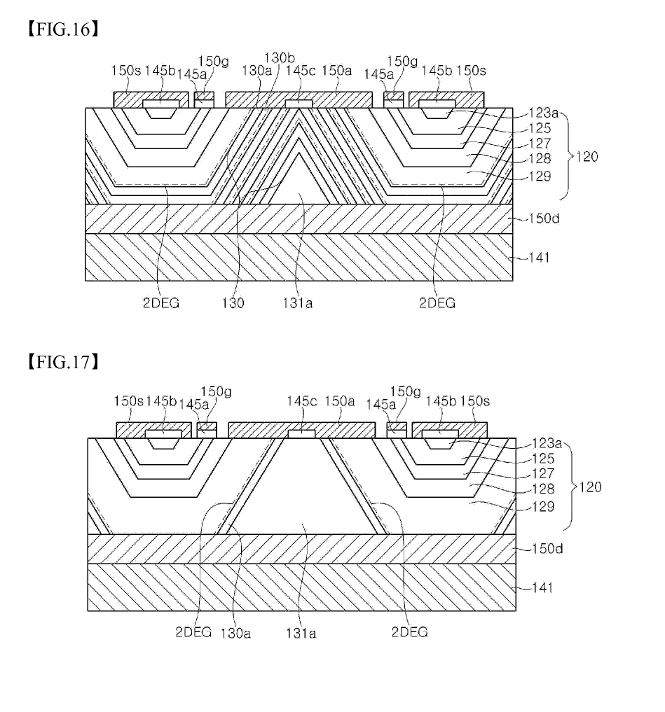

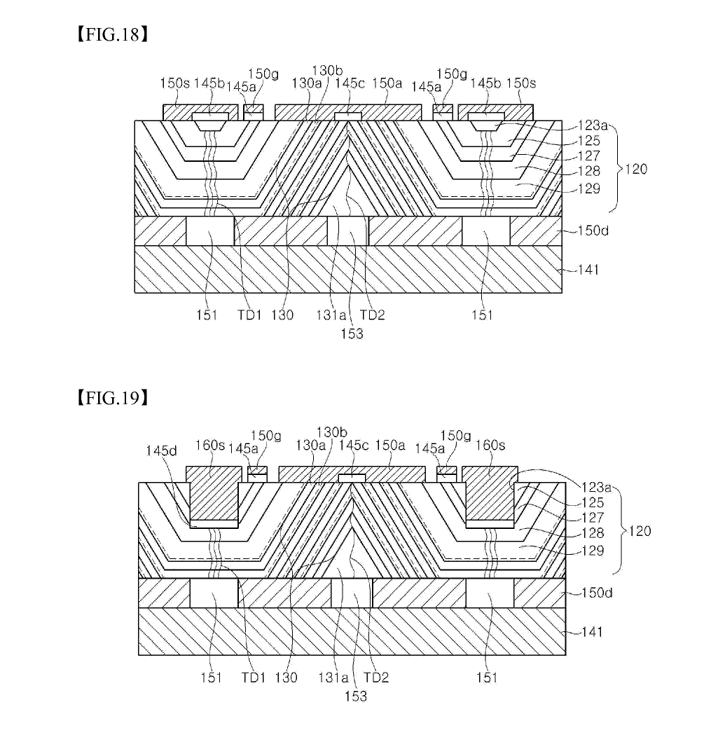

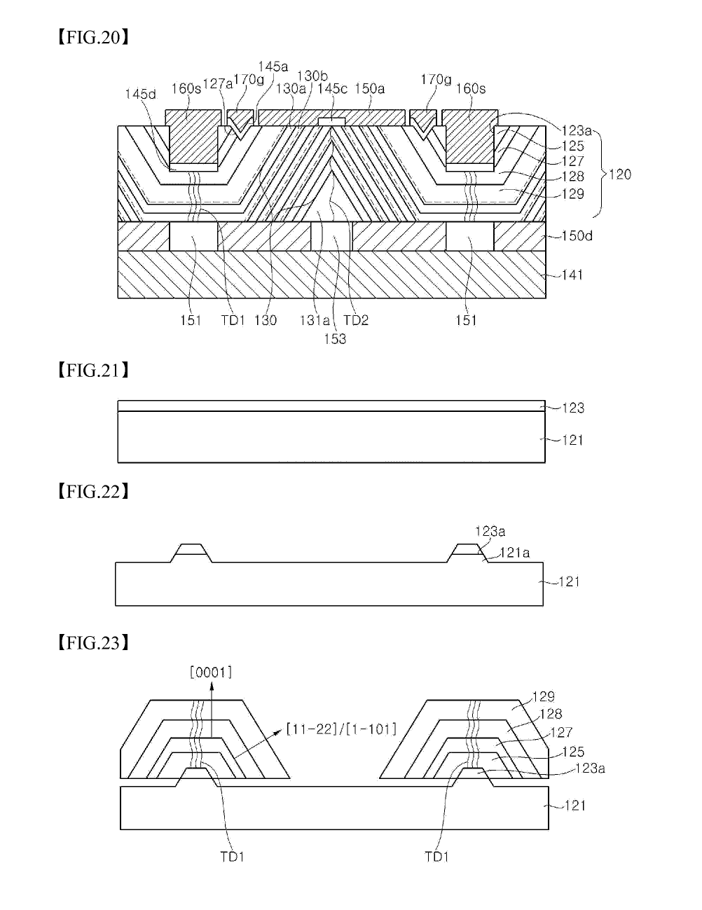

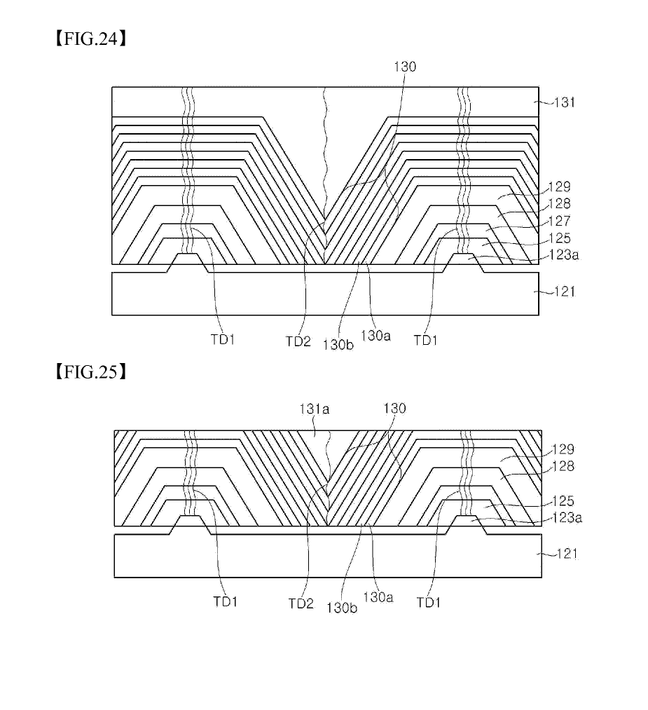

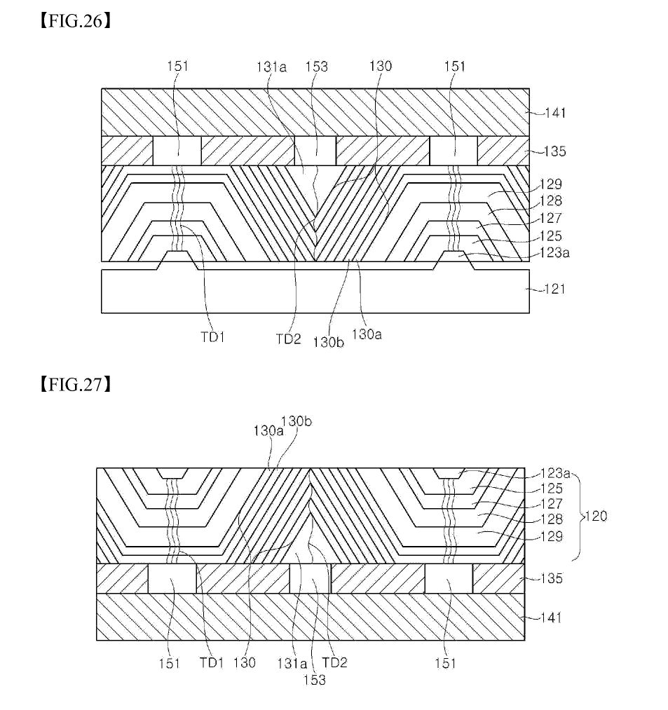

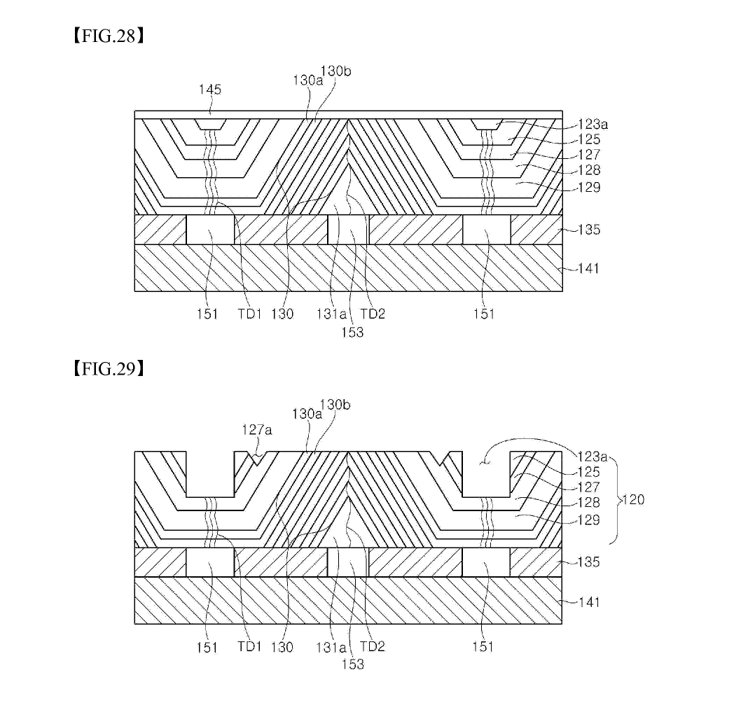

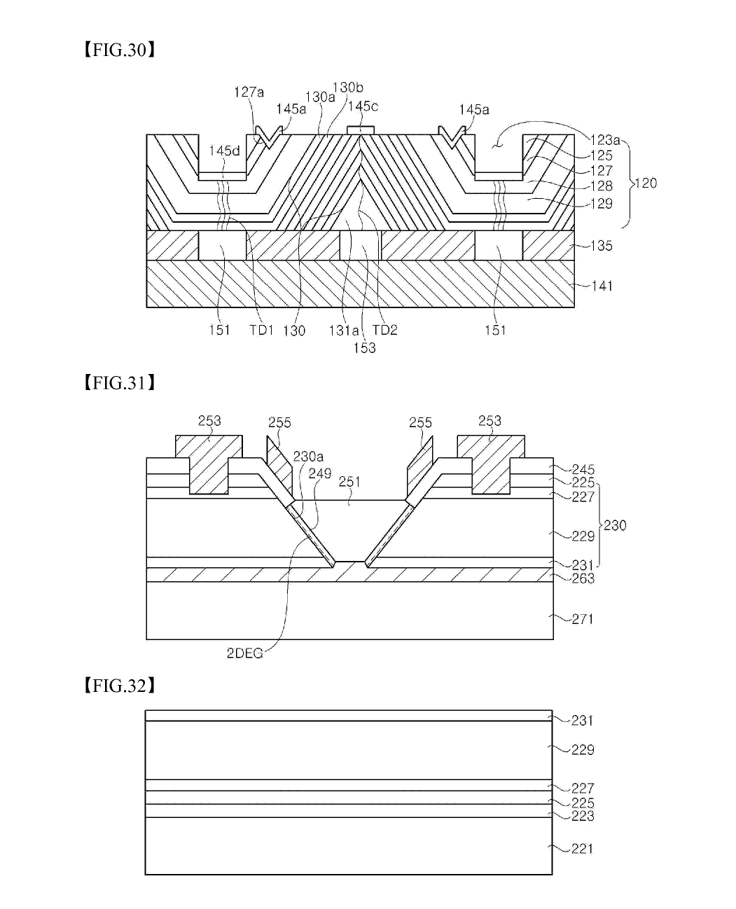

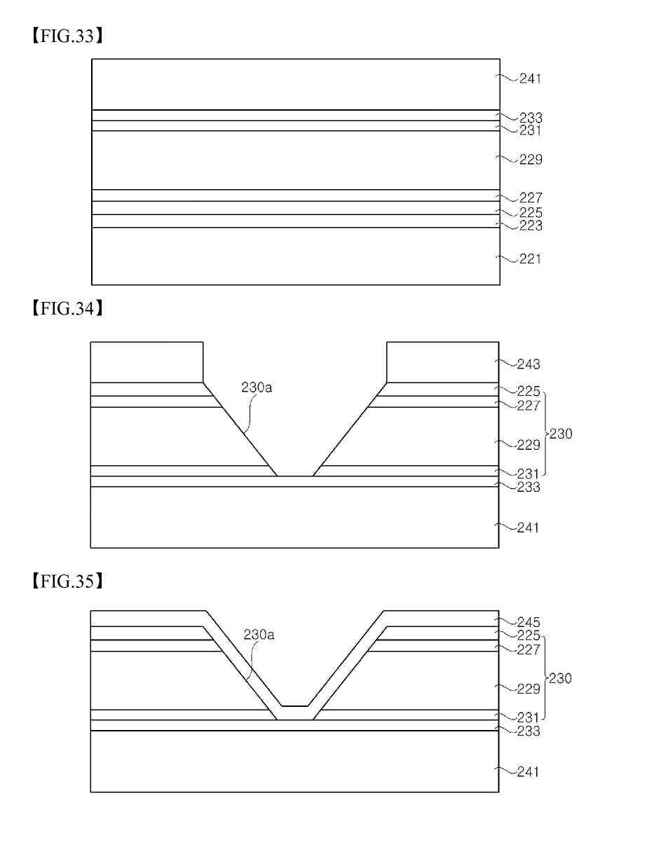

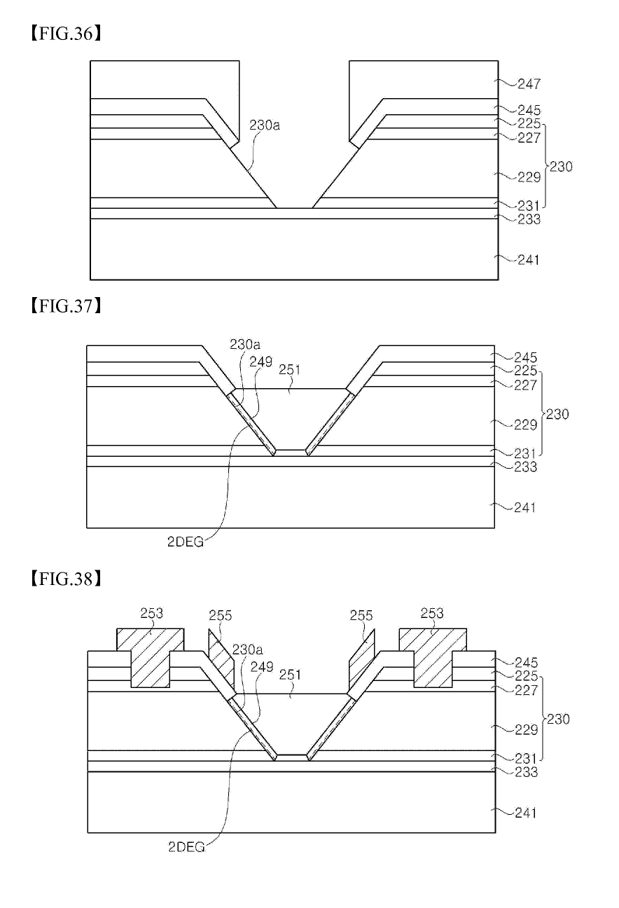

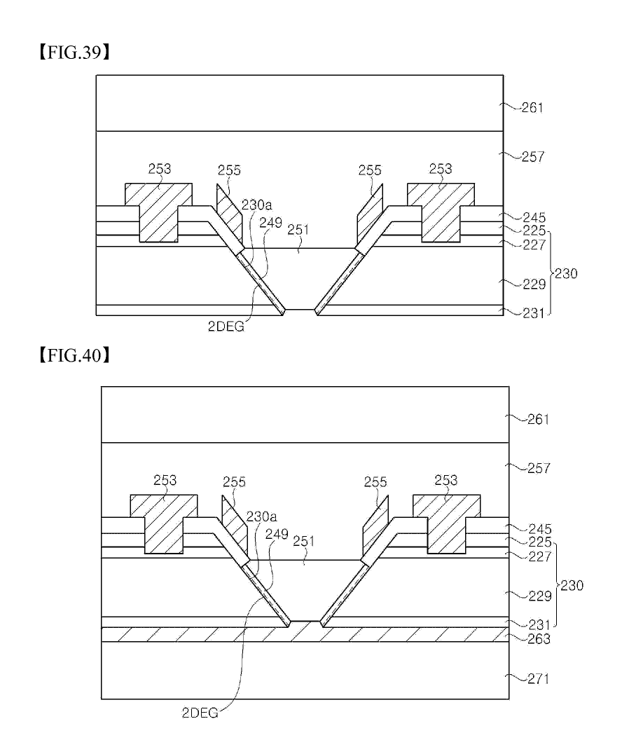

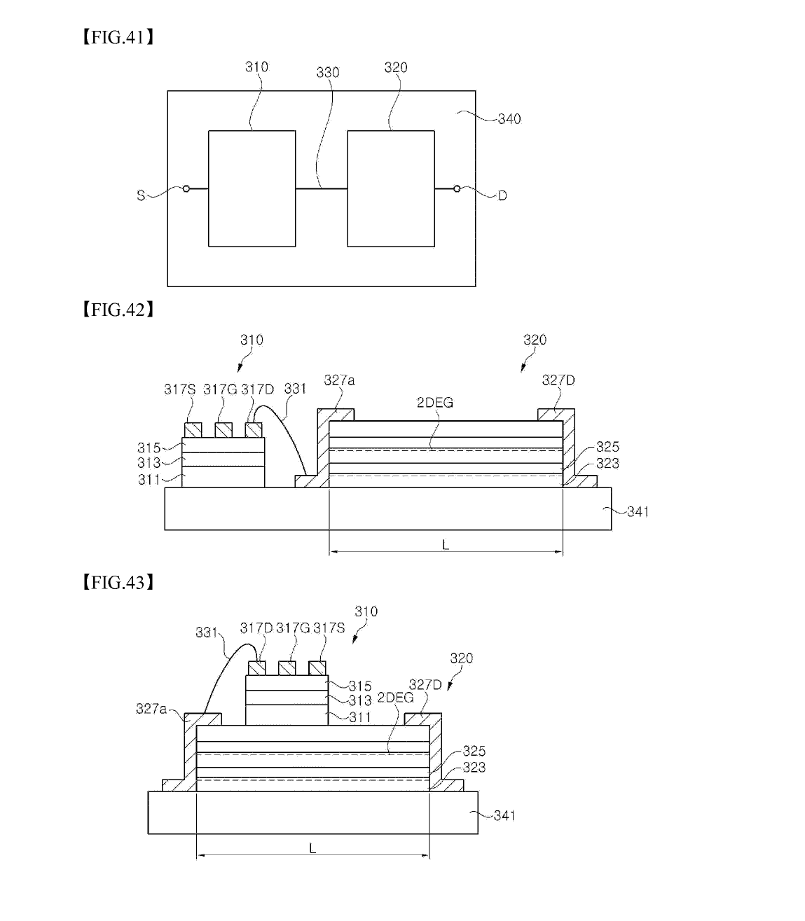

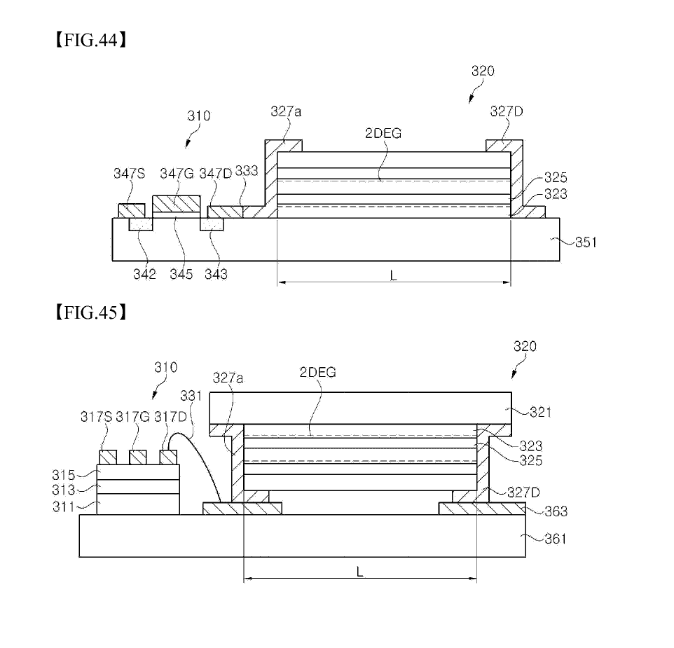

FIG. 14 and FIG. 15 are sectional views illustrating a method for manufacturing the group III-V based transistor according to the third embodiment of the present invention.

FIG. 16 is a schematic sectional view of a gallium nitride transistor according to a sixth embodiment of the present invention.

FIG. 17 is a schematic sectional view of a gallium nitride transistor according to a seventh embodiment of the present invention.

FIG. 18 is a schematic sectional view of a gallium nitride transistor according to an eighth embodiment of the present invention.

FIG. 19 is a schematic sectional view of a gallium nitride transistor according to a ninth embodiment of the present invention.

FIG. 20 is a schematic sectional view of a gallium nitride transistor according to a tenth embodiment of the present invention.

FIG. 21 to FIG. 28 are sectional views illustrating a method for manufacturing the gallium nitride transistor according to the eighth embodiment of the present invention.

FIG. 29 and FIG. 30 are sectional views illustrating a method for manufacturing the gallium nitride transistor according to the tenth embodiment of the present invention.

FIG. 31 is a schematic sectional view of the nitride transistor according to the ninth embodiment of the present invention.

FIG. 32 to FIG. 40 are sectional views illustrating a method for manufacturing the is nitride transistor according to the ninth embodiment of the present invention.

FIG. 41 is a schematic block diagram of a hybrid transistor according to embodiments of the present invention.

FIG. 42 is a schematic sectional view of a hybrid transistor according to a tenth embodiment of the present invention.

FIG. 43 is a schematic sectional view of a hybrid transistor according to an eleventh embodiment of the present invention.

FIG. 44 is a schematic sectional view of a hybrid transistor according to a twelfth embodiment of the present invention.

FIG. 45 is a schematic sectional view of a hybrid transistor according to a thirteenth embodiment of the present invention.

### DETAILED DESCRIPTION OF THE ILLUSTRATED EMBODIMENTS

Exemplary embodiments of the present invention will now be described in detail with reference to the accompanying drawings. The following embodiments are given by way of illustration to provide thorough understanding of the present invention to those skilled in the art, and the present invention may be embodied in different ways. It should be noted that the drawings are not to precise scale and some of the dimensions, such as width, length, thickness, and the like, are exaggerated for clarity of description in the drawings. Like elements are denoted by like reference numerals throughout the specification and the accompanying drawings.

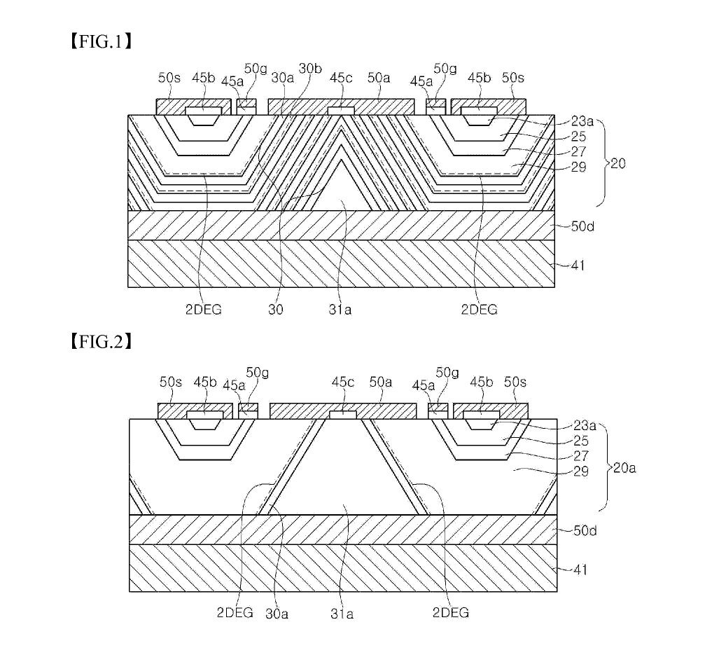

FIG. 1 is a schematic sectional view of a group III-V based transistor according to a first embodiment of the present invention.

Referring to FIG. 1, the group III-V based transistor includes a semiconductor stack 20, source electrodes 50s, gate electrodes 50g, and a drain electrode 50d. In addition, the group III-V based transistor may include a gate insulation layer 45a, a first insulation layer 45b, a second insulation layer 45c, and a substrate 41.

The semiconductor stack 20 may include stripes 23a, a first conductive type first III-V based semiconductor layer 25, a second conductive type III-V based semiconductor layer 27, a first conductive type second III-V based semiconductor layer 29, a superlattice structure 30, and a planarization layer 31a. Here, the first conductive type may be n-type and the second conductive type may be p-type, or vice versa. Here, the “III-V based semiconductor” may be a GaAs, GaP or GaN semiconductor, and may include a binary, tertiary or quaternary semiconductor. Although a transistor using a gallium nitride semiconductor will be mainly described hereinafter, it should be understood that the present invention is not limited to the gallium nitride semiconductor.

The stripes 23a may have a unidirectionally elongated structure. For example, the stripes 23a may have a longitudinal direction of <1-100> or <11-20>. Further, the stripe 23a may include c-faces as lower surfaces thereof. The stripes 23a may be formed of, for example, first conductive type gallium nitride.

On the other hand, the first conductive type first III-V based semiconductor layer 25 surrounds the lower surfaces and side surfaces of the stripes 23a. The first III-V based semiconductor layer 25 may be formed of the same III-V based semiconductor as that of the stripes 23a, whereby two layers may be combined to form a single III-V based semiconductor layer. For example, the first III-V based semiconductor layer 25 may be formed of gallium nitride doped with impurities (for example, silicon). The first conductive type first III-V based semiconductor layer 25 includes an upper surface, a lower surface, and a side surface. The lower surface of the first III-V based semiconductor layer 25 may be a c-face and the side surface thereof may be a (11-22) or (1-101) face, without being limited thereto. When the first III-V based semiconductor layer 25 is a gallium nitride (GaN) semiconductor layer, the upper surface of the first III-V based semiconductor layer 25 may be an N-face and the lower surface thereof may be a Ga-face.

The second conductive type III-V based semiconductor layer 27 surrounds the lower surface and the side surface of the first III-V based semiconductor layer 25. As shown in FIG. 1, a portion of the second conductive type III-V based semiconductor layer 27 is exposed to an upper surface of the semiconductor stack 20. The second conductive type III-V based semiconductor layer 27 may be formed of GaN doped with impurities (for example, magnesium).

The first conductive type second III-V based semiconductor layer 29 surrounds a lower surface and a side surface of the second conductive type III-V based semiconductor layer 27. Accordingly, the second conductive type III-V based semiconductor layer 27 is disposed between the first III-V based semiconductor layer 25 and the second III-V based semiconductor layer 29. The second III-V based semiconductor layer 29 may be formed of, for example, GaN, and may be partially exposed to the upper surface of the semiconductor stack 20, as shown in the drawings. The first conductive type second III-V based semiconductor layer 29 may be composed of a semiconductor layer doped with impurities (for example, silicon), without being limited thereto. For example, the first conductive type second III-V based semiconductor layer 29 may include a first conductive type semiconductor layer that is not doped with any impurities.

Both the second conductive type III-V based semiconductor layer 27 and the second III-V based semiconductor layer 29 may have the lower surfaces and the side surfaces, the plane directions of which are the same as those of the first III-V based semiconductor layer 25.

On the other hand, the superlattice structure 30 covers the side surface of the first conductive type second III-V based semiconductor layer 29. The superlattice structure 30 has a structure in which a plurality of first channel layers 30a and a plurality of second channel layers 30b are alternately stacked one above another. A portion of the superlattice structure 30 may extend to surround the lower surface of the second III-V based semiconductor layer 29.

The first channel layers 30a and the second channel layers 30b are formed of III-V based semiconductors having different energy band-gaps. For example, the first channel layers 30a are formed of AlGaN having a relatively large energy band-gap and the second channel layers 30b are formed of GaN having a relatively small energy band-gap. In this case, 2DEG regions are formed near interfaces of the second channel layers 30b having a relatively small energy band-gap. On the contrary, when the first channel layers 30a are formed of InGaN having a relatively small energy band-gap and the second channel layers 30b are formed of GaN having a relatively large energy band-gap, the 2DEG regions are formed near interfaces of the first channel layers 30a having a relatively small energy band-gap.

On the other hand, when the semiconductor stack 20 is formed of gallium nitride, high density 2DEG channels may be formed using electric fields resulting from spontaneous polarization caused by a Wurtzite structure of GaN and piezoelectric polarization caused by a difference in lattice parameter between the first channel layers 30a and the second channel layers 30b, thereby enhancing electron mobility.

As shown in FIG. 1, the 2DEG regions extend from the upper surface of the semiconductor stack 20 to the lower surface thereof along the side surface of the second III-V based semiconductor layer 29. In addition, some 2DEG regions may be parallel to the lower surface of the second III-V based semiconductor layer 29. Further, as shown in FIG. 1, at least some of the first channel layers 30a may be exposed to the upper surface and the lower surface of the semiconductor stack 20. Further, at least some of the second channel layers 30b may be exposed to the upper surface and the lower surface of the semiconductor stack 20.

The planarization layer 31a is disposed on the lower surface of the semiconductor stack 20 such that the overall lower surface of the semiconductor stack 20 becomes a flat surface. The planarization layer 31a may be formed of a III-V based semiconductor, for example, GaN.

The source electrodes 50s may be electrically connected to the first conductive type first III-V based semiconductor layer 25 or to the stripes 23a and the first conductive type first III-V based semiconductor layer 25. The source electrodes 50s are formed of a material capable of forming ohmic contact with the first conductive type first III-V based semiconductor layer. In addition, the source electrodes 50s may be electrically connected to the second conductive type III-V based semiconductor layer 27.

The gate electrode 50g is disposed between the first III-V based semiconductor layer 25 and the 2DEG region to form a channel when turned on. As shown in FIG. 1, the gate electrode 50g is disposed on an exposed region of the second conductive type III-V based semiconductor layer 27. Further, the gate insulation layer 45a is disposed between the gate electrode 50g and the semiconductor stack 20. The gate insulation layer 45a may be composed of, for example, a silicon oxide layer or a silicon nitride layer, without being limited thereto. In some embodiments, the gate electrode 50g may form Schottky contact with the upper surface of the semiconductor stack 20 without the gate insulation layer 45 an interposed therebetween.

A current spreading layer 50a may be disposed on the upper surface of the semiconductor stack 20. When the transistor is turned on, the current spreading layer 50a disperses carriers, which are introduced from the source electrodes 50s through the gate electrodes, over a wide area. The current spreading layer 50a may be connected to the 2DEG regions. Particularly, the current spreading layer 50a connects the second III-V based semiconductor layer 29 to the second channel layers 30b to disperse the carriers supplied from the source electrodes 50s to the second channel layers 30b.

On the other hand, the drain electrode 50d forms ohmic contact with the lower surface of the semiconductor stack 20. As shown, the drain electrode 50d may be connected to the 2DEG regions. The drain electrode 50d may be composed of, for example, a metal layer, such as an Al or Ni/Ti/Au layer, and may be disposed between the support substrate 41 and the semiconductor stack 20. The support substrate 41 may be a conductive or insulating substrate. For example, the support substrate 41 may be formed of various materials such as AlN, AlSi, Cu or the like.

A dislocation defect area having a relatively large amount of dislocations transferred from the stripe 23a is formed under the lower surface of the stripes 23a. When the source electrodes 50s are connected to the stripes 23a, current leakage can occur through dislocations from the source electrodes 50s. To prevent this problem, the first insulation layer 45b may be disposed between the source electrodes 50s and the stripes 23a.

In addition, a dislocation defect area may be formed in an intermediate region between adjacent stripes 23a. Accordingly, the second insulation layer 45c is disposed between the current spreading layer 50a and the semiconductor stack 20 to prevent current leakage. The first insulation layer 45b and the second insulation layer 45c may be formed of the same material as that of the gate insulation layer 45a, without being limited thereto.

As shown, a pair of source electrodes 50s may be disposed symmetrical to each other and a pair of gate electrodes 50g may be disposed symmetrical to each other. To this end, a pair of stripes 23a may be disposed symmetrical to each other, so that the semiconductor stack 20 has a symmetrical structure, as shown in FIG. 1. On the other hand, as shown therein, the drain electrode 50d may be continuously disposed on the lower surface of the semiconductor stack 20. Alternatively, although not shown, the drain electrode 50d may be disposed only in some areas of the lower surface of the semiconductor stack 20.

Next, operation of the transistor according to this embodiment will be described.

First, upon application of positive voltage to the gate electrodes 50g, channels are formed in the second conductive type III-V based semiconductor layer 27 below the gate electrodes 50g. As a result, a voltage difference is created between the source electrodes 50s and the drain electrode 50d and causes migration of carriers (electrons) from the source electrodes 50s to the drain electrode 50d. Here, the carriers migrate from the first III-V based semiconductor layer 25 to the second III-V based semiconductor layer 29 through the channels below the gate electrodes 50g, spread to the plurality of second channel layers 30b via the current spreading layer 50a, and then are moved to the drain electrode 50d through the 2DEG regions formed in the second channel layers 30b.

As such, according to the present embodiment, it is possible to move the carriers at high velocity using 2DEG.

On the other hand, since the second conductive type III-V based semiconductor layer 27 is disposed between the first conductive type first III-V based semiconductor layer 25 and the second III-V based semiconductor layer 29, the transistor according to the present embodiment exhibits high withstand voltage characteristics when turned off. Furthermore, the superlattice structure 30 interposed between the drain electrode 50d and the source electrode 50s further enhances withstand voltage characteristics of the transistor.

In this embodiment, the structure 30 is not limited to the superlattice structure and may have a multilayer structure in which the first channel layers 30a and the second channel layers 30b are stacked plural times.

Although many components are described above, it should be understood that the present invention does not essentially include all of these components. For example, the current spreading layer 50a, the first insulation layer 45b or the second insulation layer 45c may be omitted from the transistor according to the present invention. In addition, the number of first channel layers 30a and the number of second channel layers 30b are not particularly limited.

FIG. 2 is a schematic sectional view of a group III-V based transistor according to a second embodiment of the present invention.

Referring to FIG. 2, although the transistor according to this embodiment is generally similar to the transistor described with reference to FIG. 1, a semiconductor stack 20a according to this embodiment includes a single first channel layer 30a. That is, the group III-V based transistor shown in FIG. 1 includes the superlattice structure 30, which includes the plurality of first channel layers 30a, whereas the semiconductor stack 20a according to this embodiment includes a single first channel layer 30a.

The first channel layers 30a are formed of a III-V based semiconductor having a different energy band-gap from that of the first conductive type second III-V based semiconductor layer 29. For example, the first channel layers 30a may be formed of AlGaN. A 2DEG region is formed near an interface between the second III-V based semiconductor layer 29 and each of the first channel layers 30a by the first channel layer 30a.

A drain electrode 50d may be connected to the 2DEG region. To this end, the drain electrode 50d may adjoin the second III-V based semiconductor layer 29 and the first channel layer 30a.

On the other hand, gate electrodes 50g, a gate insulation layer 45a, source electrodes 50s, a current spreading layer 50a, a first insulation layer 45b, and a second insulation layer 45b are similar to those of the transistor described in FIG. 1, and detailed descriptions thereof will be omitted to avoid repeated descriptions.

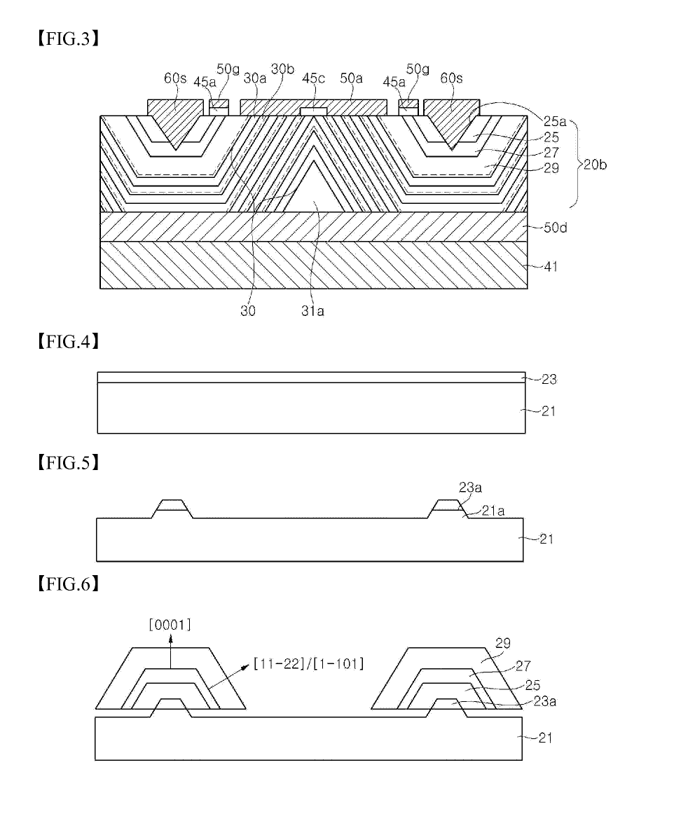

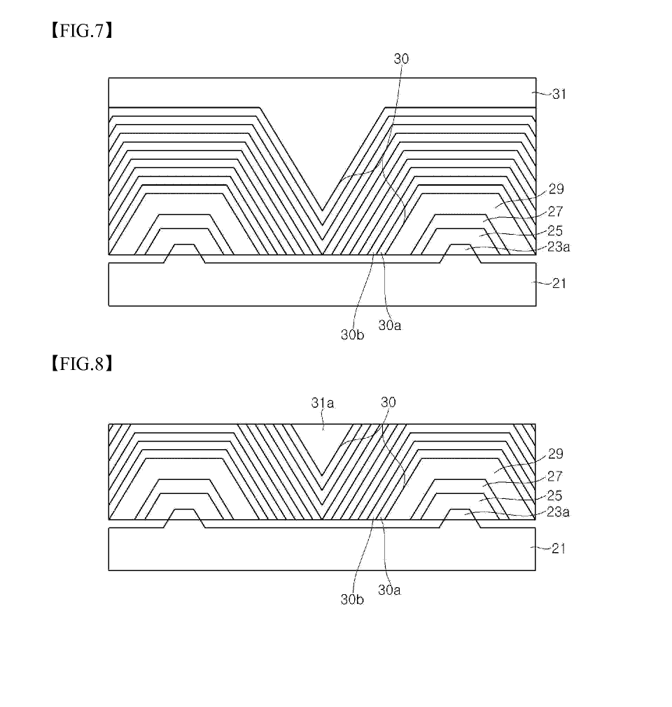

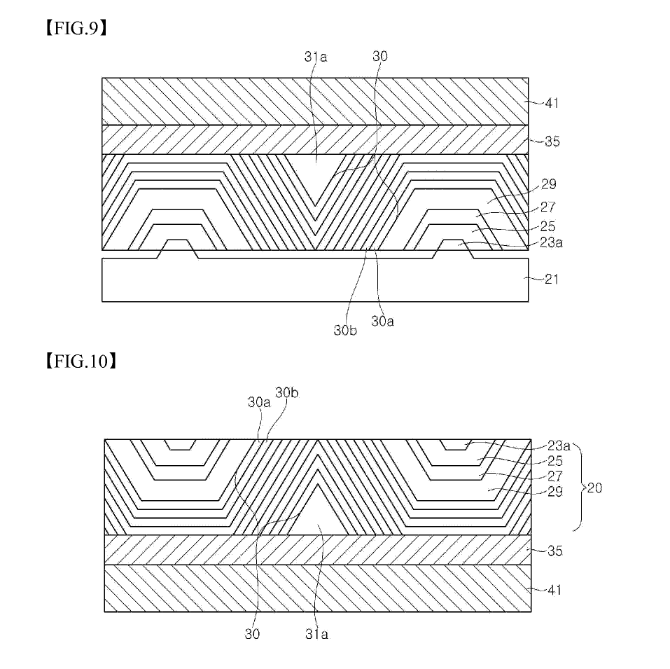

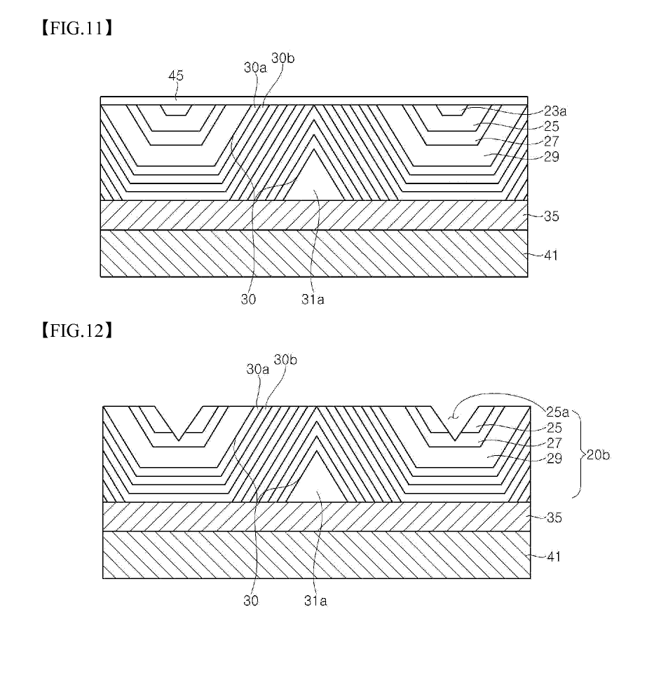

FIG. 3 is a schematic sectional view of a group III-V based transistor according to a third embodiment of the present invention.

Referring to FIG. 3, although the transistor according to this embodiment is generally similar to the transistor described with reference to FIG. 1, a semiconductor stack 20b of this embodiment includes recesses 25a.

Specifically, the recesses 25a are formed on a first conductive type first III-V based semiconductor layer 25 to expose a second conductive type III-V based semiconductor layer 27. The recesses 25a are formed by wet etching or dry etching and wet etching an upper surface of a gallium nitride semiconductor stack 20b, which is an N-face. Etching damage due to formation of the recesses does not occur, or will be removed. Although the stripes 23a as shown in FIG. 1 may be removed by formation of the recesses, it is not necessary to completely remove the stripes 23a.

Source electrodes 60s are connected to the first III-V based semiconductor layer 25 and to the second conductive type III-V based semiconductor layer 27 exposed to the recesses 25a.

FIG. 14 is a schematic sectional view of a group III-V based transistor according to a fourth embodiment of the present invention.

Referring to FIG. 14, the group III-V based transistor according to this embodiment is generally similar to the group III-V based transistor described with reference to FIG. 3 except for a gate insulation layer 45a and gate electrodes 60g.

Specifically, the gate insulation layer 45a extends to a region between source electrodes 60s and covers an exposed surface of a second III-V based semiconductor layer 29 and exposed 2DEG regions. The gate insulation layer 45a may also cover a dislocation defect area formed in an intermediate region between the source electrodes 60s.

Although the gate insulation layer 45a is continuously formed between the source electrodes 60s in this embodiment, the present invention is not limited thereto. Alternatively, the gate insulation layer may be divided into two or more regions. For example, when a pair of adjacent source electrodes 60s is formed, the gate insulation layer 45a may be divided into gate insulation layers placed adjacent to the source electrodes 45a and separated from each other.

On the other hand, the gate electrodes 60g are disposed on the gate insulation layer 45a. As compared with the gate electrode 50g shown in FIG. 3, the gate electrode 60g further extends toward an intermediate region between the source electrodes 60s. That is, the gate electrodes 60g are placed above the second conductive type III-V based semiconductor layer 27 and extend above channel layers 30a, 30b exposed to the upper surface of the semiconductor stack 20b.

The gate electrodes 60g adjacent to the source electrodes 60s may be separated from each other so as not to cover the intermediate region between the source electrodes 60s. However, it should be understood that the present invention is not limited thereto and the gate electrodes 60g may be connected to each other.

In this embodiment, the gate electrodes 60g serve to disperse charges introduced from the source electrodes 60s to the channel layers 30a, 30b.

The gate insulation layer 45a and the gate electrodes 60g according to this embodiment may also be applied to the group III-V based transistors according to the first and second embodiments described above.

FIG. 15 is a schematic sectional view of a group III-V based transistor according to a fifth embodiment of the present invention.

Referring to FIG. 15, although the group III-V based transistor according to this embodiment is generally similar to the group III-V based transistor described with reference to FIG. 14, a semiconductor stack 20c according to this embodiment further includes recesses 27a.

Specifically, the semiconductor stack further includes the recesses 27a formed on an upper surface of the semiconductor stack 20c in addition to recesses 25a formed on a first conductive type first III-V based semiconductor layer 25. The recesses 27a are formed by wet etching or dry etching and wet etching an exposed surface of the second conductive type III-V based semiconductor layer 27. The recesses 27a may be formed together with the recesses 25a.

By removal of the exposed portion of the second conductive type III-V based semiconductor layer 27, it is possible to remove charge trap sites including an etching damage layer, impurities, and the like, which can remain in channel areas below the gate electrodes 70g.

The gate insulation layer 45a covers the second conductive type III-V based semiconductor layer 27 within the recesses 27a, and the gate electrodes 70g are disposed on the gate insulation layer 45a within the recesses 27a.

The recesses 27a, the gate insulation layer 45a and the gate electrodes 70g according to this embodiment may also be applied to the group III-V based transistors described with reference to FIG. 1 and FIG. 2. In addition, as in the group III-V based transistor shown in FIG. 1 and FIG. 2, the gate electrodes 50g may be formed independent of the current spreading layer 50a.

FIG. 4 to FIG. 13 are sectional views illustrating a method for manufacturing the group III-V based transistor according to the first embodiment.

Referring to FIG. 4, a III-V based semiconductor layer 23 is grown on a growth substrate 21. The growth substrate 21 may be any substrate capable of growing the III-V based semiconductor layer 23 thereon, and may include, for example, a c-face sapphire substrate on which c-face GaN may be grown.

The semiconductor layer 23 and III-V based semiconductor layers described below may be grown by MOCVD or MBE. The semiconductor layer 23 may include a nucleus layer (not shown). The semiconductor layer 23 may be formed of, for example, GaN, and has a c-face growth plane.

Referring to FIG. 5, stripes 23a are formed by patterning the semiconductor layer 23. Patterning of the semiconductor layer 23 may be performed by photolithography and etching using a photoresist. In the course of patterning the semiconductor layer 23, the growth substrate 21 may also be partially removed to form protrusions 21a under the stripes 23a.

As shown, the stripes 23a may have inclined side surfaces. However, it should be understood that the present invention is not limited thereto and the side surfaces of the stripes may be perpendicular to the surface of the substrate 21.

Referring to FIG. 6, a first conductive type first III-V based semiconductor layer 25, a second conductive type III-V based semiconductor layer 27 and a first conductive type second III-V based semiconductor layer 29 are grown on the stripes 23a.

The first conductive type first III-V based semiconductor layer 25 is grown on upper and side surfaces of the stripes 23a; the second conductive type III-V based semiconductor layer 27 is grown on upper and side surfaces of the first conductive type first III-V based semiconductor layer 25; and the first conductive type second III-V based semiconductor layer 29 is grown on upper and side surfaces of the second conductive type III-V based semiconductor layer 27.

The upper surfaces of the semiconductor layers 25, 27, 29 are c-faces, grown in a direction of [0001], and become Ga-faces. On the other hand, the side surfaces of the semiconductor layers 25, 27, 29 are grown in a direction of [11-22] or [1-101] and become (11-22) or (1-101) faces. The lateral directions of the semiconductor layers 25, 27, 29 are determined depending upon a longitudinal direction of the stripes 23a. For example, when the stripes 23a have a longitudinal direction of <1-100>, the side surface of the stripes becomes a (11-22) face, and when the stripes 23a have a longitudinal direction of <11-20>, the side surface of the stripes becomes a (1-101) face. The (11-22) face and the (1-101) face are semi-polar faces.

Growth rates of the upper and side surfaces of each of the semiconductor layers 25, 27, 29 may be controlled by adjusting growth conditions, particularly, growth temperature and/or flux of each of source gases therefor. Accordingly, a vertical thickness of each of the semiconductor layers 25, 27, 29 may be controlled to be the same as or different from a lateral thickness thereof. Particularly, as shown in FIG. 6, the vertical thickness of the second conductive type semiconductor layer 27 may be greater than the lateral thickness thereof.

On the other hand, since dislocations are transferred in an upward direction from the stripes 23a, dislocation defect areas are formed on the upper surfaces of the stripes 23a, whereas regions in the lateral direction of the stripes have a very low dislocation density.

As shown in FIG. 6, the second III-V based semiconductor layer 29 grown on each of the stripes 23a may be separated from other second III-V based semiconductor layers 29.

Referring to FIG. 7, a superlattice structure 30 is grown by alternately stacking first channel layers 30a and second channel layers 30b on the first conductive type second III-V based semiconductor layer 29.

The first channel layers 30a are formed of a III-V based semiconductor, for example, AlGaN, which has a different energy band-gap from those of the second III-V based semiconductor layer 29 and the second channel layers 30b. The second channel layers 30b may be formed of, for example, GaN. In this case, 2DEG regions are formed in the second channel layers 30b having a relatively low energy band-gap.

On the other hand, as growth of the superlattice structure 30 continues, the superlattice structures 30 grown on adjacent stripes 23a may be connected to each other. Here, lots of dislocations are created in an intermediate region between the stripes 23a, that is, in a region where the superlattice structures 30 grown on the adjacent stripes 23a meet each other, thereby forming a dislocation defect area.

The number of first channel layers 30a and the number of second channel layers 30b in the superlattice structure 30 are not particularly limited. In addition, although the present embodiment includes the superlattice structure 30, it should be understood that the present invention is not limited to the superlattice structure, and the structure may have a multilayer structure in which first channel layers and second channel layers are alternately stacked one above another.

A planarization layer 31 is grown on the superlattice structure 30 to fill a groove formed on an upper surface of the superlattice structure 30. The planarization layer 31 may be grown as a III-V based semiconductor layer, for example, a GaN layer.

Referring to FIG. 1-08, the superlattice structure 30 is exposed by partially etching the planarization layer 31. The superlattice structure 30 may also be partially removed, and the planarization layer 31a remains in the groove formed by the superlattice structure 30.

By partial removal of the superlattice structure 30, some of the first channel layers 30a and some of the second channel layers 30b are exposed to the outside. As a result, the 2DEG regions formed on the second channel layers 30b are also exposed.

Referring to FIG. 9, a support substrate 41 is then attached to the upper surface of the superlattice structure 30. The support substrate 41 may be bonded to a metal layer 35 of Al or Ni/Ti/Au formed on the superlattice structure 30 and the planarization layer 31a via a bonding metal. Alternatively, the support substrate 41 may be formed on the metal layer 35 by plating. The support substrate 41 may include a ceramic or semiconductor substrate such as an AlN or AlSi substrate, or a metal substrate including Cu, Mo and/or W. Alternatively, the support substrate 41 may be integrally formed with the metal layer 35.

The metal layer 35 may be connected to the first channel layers 30a and the second channel layers 30b and thus may also be connected to the 2DEG regions.

Referring to FIG. 10, the growth substrate 21 is separated from the semiconductor layers. The growth substrate 21 may be separated from the semiconductor layers including the stripes 23a by, for example, laser lift-off.

In the course of separating the growth substrate 21 by laser lift-off, the exposed surfaces of the semiconductor layers can be damaged by laser beams, and Ga droplets can remain thereon. Thus, the exposed surfaces of the semiconductor layers are entirely recessed by wet etching or dry etching and wet etching, thereby removing the damaged surface or the Ga droplets. Dry etching may be carried out by reactive ion etching (RIE) and wet etching may be carried out using a KOH, NaOH or H₃PO₄ solution.

After separation of the growth substrate 21, the second conductive type III-V based semiconductor layer 27 may be activated by heat treatment at about 400° C. to about 950° C. in a N₂ or air atmosphere. As a result, a final semiconductor stack 20 is obtained.

The second conductive type III-V based semiconductor layer 27 may be activated before separation of the growth substrate 21. Since a space is present between the growth substrate 21 and the second conductive type III-V based semiconductor layer 27, the second conductive type III-V based semiconductor layer 27 may be activated by heat treatment at a temperature of, for example, about 900° C. in a N₂ or air atmosphere for about 60 minutes.

Referring to FIG. 11, an insulation layer 45 is deposited on the semiconductor stack 20. The insulation layer 45 may be formed of, for example, silicon oxide or silicon nitride, without being limited thereto.

Then, a gate insulation layer 45a, a first insulation layer 45b and a second insulation layer 45c may be formed by patterning the insulation layer 45 through photolithography and etching, as shown in FIG. 1. The first insulation layer 45b may be formed on the stripes 23a and the second insulation layer 45c may be formed on the planarization layer 31a.

Next, source electrodes 50s connected to the first conductive type first III-V based semiconductor layer 25, gate electrodes 50g disposed on the gate insulation layer 45a, and a current spreading layer 50a are formed, thereby providing a group III-V based transistor as shown in FIG. 1. Here, a metal layer 35 is used as the drain electrode 50d.

In this embodiment, the superlattice structure 30 is formed on the second III-V based semiconductor layer 29. Alternatively, a single first channel layer 30a may be formed thereon instead of the superlattice structure 30, thereby providing the group III-V based transistor, as shown in FIG. 2.

FIG. 12 and FIG. 13 are sectional views illustrating a method for manufacturing the group III-V based transistor according to the third embodiment.

Referring to FIG. 12, the growth substrate is separated through processes described with reference to FIG. 4 to FIG. 10. After separation of the growth substrate 21, the exposed surface of the semiconductor layers may be subjected to wet etching or dry etching and wet etching.

Then, as shown in FIG. 12, recesses 25a are formed on the first conductive type III-V based semiconductor layer 25. The second conductive type III-V based semiconductor layer 27 is exposed through the recesses 25a. The recesses 25a may be formed by wet etching using a KOH, NaOH or H₃PO₄ solution or by plasma dry etching and wet etching.

After formation of the recesses 25a, the second conductive type III-V based semiconductor layer 27 may be activated. As a result, a final semiconductor stack 20b is obtained.

In this embodiment, the second conductive type III-V based semiconductor layer 27 is activated after formation of the recesses 25a. Alternatively, as shown in FIG. 1210, the second conductive type III-V based semiconductor layer 27 may be activated after separation of the growth substrate 21 and before formation of the recesses 25a, or activated before separation of the growth substrate 21.

Here, as activation of the second conductive type III-V based semiconductor layer is performed after formation of the recesses 25a, hydrogen can be extracted from the second conductive type III-V based semiconductor layer through the recesses 25a, thereby promoting activation of the second conductive type III-V based semiconductor layer 27.

Referring to FIG. 13, then, a gate insulation layer 45a and a second insulation layer 45c are formed, followed by formation of source electrodes 60s, gate electrodes 50g and a current spreading layer 50a, thereby providing a group III-V based transistor as shown in FIG. 2. Here, a metal layer 35 is used as the drain electrode 50d.

The source electrodes 60s are connected not only to the first III-V based semiconductor layer 25, but also to the second conductive type III-V based semiconductor layer 27 through the recesses 25a.

According to this embodiment, the second conductive type III-V based semiconductor layer 27 is exposed through the recesses 25a, thereby facilitating activation of the second conductive type III-V based semiconductor layer 27.

In addition, since the source electrodes 60s are connected to the second conductive type III-V based semiconductor layer 27 through the recesses 25a, the source electrodes 60s have a narrower width than the source electrodes 50s of the transistor shown in FIG. 1. This structure can reduce the width of the group III-V based transistor, thereby providing advantages in high integration.

According to this embodiment, the N-face of the semiconductor stack 20 is exposed to the outside by separation of the growth substrate 21. Unlike a Ga face, the N-face of the III-V based semiconductor layer can be easily etched by wet etching. Accordingly, patterning of the semiconductor stack can be achieved without etching damage, which is provided in the course of etching the Ga-face, thereby providing the group III-V based transistor without etching damage.

On the other hand, when patterning the insulation layer 45 as shown in FIG. 1311 after formation of the recesses 25a of FIG. 1-412, the gate insulation layer 45a and the second insulation layer 45c may be continuously formed instead of separation thereof from each other, thereby forming the gate insulation layer 45a, as shown in FIG. 14. Then, the source electrodes 60s and gate electrodes 60g are formed, thereby providing a group III-V based transistor, as shown in FIG. 14.

Further, upon formation of the recesses 25a of FIG. 12, the recesses 27a of FIG. [[5]]15 may also be formed by the same wet etching process or by the same dry etching and wet etching processes, thereby providing a group III-V based transistor, as shown in FIG. 15.

FIG. 16 is a schematic sectional view of a gallium nitride transistor according to a sixth embodiment of the present invention.

Referring to FIG. 16, the gallium nitride transistor includes a semiconductor stack 120, source electrodes 150s, gate electrodes 150g and a drain electrode 150d. Further, the gallium nitride transistor may include a gate insulation layer 145a, a first insulation layer 145b, a second insulation layer 145c, a current spreading layer 150a, and a substrate 141.

On the other hand, the semiconductor stack 120 may include stripes 123a, a first conductive type first gallium nitride semiconductor layer 125, a second conductive type or high resistance (i-type) gallium nitride semiconductor layer (third gallium nitride semiconductor layer) 127, a first conductive type second gallium nitride semiconductor layer 128, a high resistance gallium nitride semiconductor layer 129, a superlattice structure 130, and a planarization layer 131a. Here, the first conductive type may be n-type and the second conductive type may be p-type, or vice versa. Here, the “gallium nitride semiconductor” may include a binary, tertiary or quaternary semiconductor, and include an i-type semiconductor as well as the n-type and p-type semiconductor.

The stripes 123a may have a unidirectionally elongated structure. For example, the stripes 123a may have a longitudinal direction of <1-100> or <11-20>. Further, the stripes 123a may include c-faces as lower surfaces thereof. The stripes 123a may be formed of, for example, first conductive type gallium nitride.

The first conductive type first gallium nitride semiconductor layer 125 surrounds the lower surfaces and side surfaces of the stripe 123a. The first gallium nitride semiconductor layer 125 may be formed of a gallium nitride semiconductor having the same composition as that of the stripes 123a, whereby two layers may be combined to form a single gallium nitride semiconductor layer. For example, the first gallium nitride semiconductor layer 125 may be formed of gallium nitride doped with impurities (for example, silicon). The first conductive type first gallium nitride semiconductor layer 125 includes an upper surface, a lower surface, and a side surface. The lower surface of the first gallium nitride semiconductor layer 125 may be a c-face and the side surface thereof may be a (11-22) or (1-101) face, without being limited thereto. In addition, the upper surface of the first gallium nitride semiconductor layer 125 may be an N-face and the lower surface thereof may be a Ga-face.

The second conductive type or high resistance gallium nitride semiconductor layer 127 surrounds the lower surface and the side surface of the first gallium nitride semiconductor layer 125. As shown in FIG. 16, a portion of the second conductive type or high resistance gallium nitride semiconductor layer 127 is exposed to an upper surface of the semiconductor stack 120. The second conductive type or high resistance gallium nitride semiconductor layer 127 may be formed of, for example, a gallium nitride semiconductor doped with impurities (for example, magnesium) or a high resistance gallium nitride semiconductor having a wider band-gap than the gallium nitride semiconductor layer 125. For example, the gallium nitride semiconductor layer 127 may be formed of p-type GaN or i-type AlGaN.

The first conductive type second gallium nitride semiconductor layer 128 surrounds a lower surface and a side surface of the third gallium nitride semiconductor layer 127. Accordingly, the third gallium nitride semiconductor layer 127 is disposed between the first gallium nitride semiconductor layer 125 and the second gallium nitride semiconductor layer 128. The second gallium nitride semiconductor layer 129 may be formed of, for example, GaN, and may be partially exposed to the upper surface of the semiconductor stack 120. The first conductive type second gallium nitride semiconductor layer 128 may be formed of n-type semiconductor doped with impurities (for example, silicon), without being limited thereto.

The high resistance (i-type) gallium nitride semiconductor layer 129 surrounds a lower surface and a side surface of the second gallium nitride semiconductor layer 128. The high resistance gallium nitride semiconductor layer 129 may be formed without impurity doping, or may be formed by counter doping impurities such as Fe, C, Zn or Mg to have high resistance.

All of the third gallium nitride semiconductor layer 127, the second gallium nitride semiconductor layer 128, and the high resistance gallium nitride semiconductor layer 129 may have the lower surfaces and the side surfaces, the plane directions of which are the same as those of the first gallium nitride semiconductor layer 125.

The superlattice structure 130 covers the side surface of the high resistance gallium nitride semiconductor layer 129. The superlattice structure 130 has a structure in which a plurality of first channel layers 130a and a plurality of second channel layers 130b are alternately stacked one above another. The first channel layers 130a and the second channel layers 130b extend from an upper surface of the semiconductor stack 120 to a lower surface thereof, and some of the first and second channel layers may surround the lower surface of the high resistance gallium nitride semiconductor layer 129.

The first channel layers 130a and the second channel layers 130b are formed of gallium nitride semiconductors having different energy band-gaps. For example, the first channel layers 130a are formed of AlGaN having a relatively large energy band-gap and the second channel layers 130b are formed of GaN having a relatively small energy band-gap. In this case, 2DEG regions are formed near interfaces of the second channel layers 130b having a relatively small energy band-gap. On the contrary, when the first channel layers 130a are formed of InGaN having a relatively small energy band-gap and the second channel layers 130b are formed of GaN having a relatively large energy band-gap, the 2DEG regions are formed near interfaces of the first channel layers 130a having a relatively small energy band-gap.

On the other hand, in the gallium nitride semiconductor stack 120, 2DEG channels of high density may be formed using electric fields resulting from spontaneous polarization caused by a Wurtzite structure and piezoelectric polarization caused by a difference in lattice parameter between the first channel layers 130a and the second channel layers 130b, thereby enhancing electron mobility.

As shown in FIG. 16, the 2DEG regions extend from the upper surface of the semiconductor stack 120 to the lower surface thereof along the side surface of the second gallium nitride semiconductor layer 128. In addition, some 2DEG regions may be parallel to the lower surface of the second gallium nitride semiconductor layer 128. Further, as shown in FIG. 16, at least some of the first channel layers 130a may be exposed to the upper surface and the lower surface of the semiconductor stack 120. Further, at least some of the second channel layers 130b may be exposed to the upper surface and the lower surface of the semiconductor stack 120

The planarization layer 131a is disposed on the lower surface of the semiconductor stack 120 such that the overall lower surface of the semiconductor stack 120 becomes a flat surface. The planarization layer 131a may be composed of a gallium nitride semiconductor layer, for example, GaN.

The source electrodes 150s may be electrically connected to the first conductive type first gallium nitride semiconductor layer 125 or to the stripes 123a and the first conductive type first III-V based semiconductor layer 125. The source electrodes 50s are formed of a material capable of forming ohmic contact with the first conductive type first gallium nitride semiconductor layer 125. In addition, the source electrodes 50s may be electrically connected to the third gallium nitride semiconductor layer 127.

The gate electrode 150g is disposed between the first gallium nitride semiconductor layer 125 and the 2DEG region to form a channel when the transistor is turned on. As shown in FIG. 16, the gate electrode 50g is disposed on an exposed region of the third gallium nitride semiconductor layer 127. Further, the gate insulation layer 145a is disposed between the gate electrode 150g and the semiconductor stack 120. The gate insulation layer 145a may be formed of, for example, silicon oxide or silicon nitride, without being limited thereto. In some embodiments, the gate electrodes 150g may form Schottky contact with the upper surface of the semiconductor stack 120 without the gate insulation layer 145a interposed therebetween.

The current spreading layer 150a may be disposed on the upper surface of the semiconductor stack 120. When the transistor is turned on, the current spreading layer 150a disperses carriers, which are introduced from the source electrodes 150s through the gate electrodes, over a wide area. The current spreading layer 150a may be connected to the 2DEG regions. Particularly, the current spreading layer 150a connects the second gallium nitride semiconductor layer 129 to the second channel layers 130b to disperse the carriers supplied from the source electrodes 150s to the second channel layers 130b.

The drain electrode 150d forms ohmic contact with the lower surface of the semiconductor stack 120. As shown, the drain electrode 150d may be connected to the 2DEG regions. The drain electrode 50d may be composed of, for example, a metal layer, such as an Al or Ni/Ti/Au layer, and may be disposed between the support substrate 141 and the semiconductor stack 120. The support substrate 141 may be a conductive or insulating substrate. For example, the support substrate 141 may be formed of various materials such as AlN, AlSi, Cu or the like.

A dislocation defect area having a relatively large amount of dislocations transferred from the stripe 123a is formed under the lower surface of the stripe 123a. When the source electrodes 150s are connected to the stripes 123a, current leakage can occur through dislocations from the source electrodes 150s. To prevent this problem, the first insulation layer 145b may be placed between the source electrodes 150s and the stripes 123a.

In addition, a dislocation defect area may be formed in an intermediate region between adjacent stripes 23a. Accordingly, the second insulation layer 145c is disposed between the current spreading layer 150a and the semiconductor stack 120 to prevent current leakage. The first insulation layer 145b and the second insulation layer 145c may be formed of the same material as that of the gate insulation layer 145a, without being limited thereto.

As shown, a pair of source electrodes 150s may be disposed symmetrical to each other and a pair of gate electrodes 150g may be disposed symmetrical to each other. Particularly, the 2DEG regions may be formed to have a mirror symmetry structure. To this end, a pair of stripes 23a may be disposed symmetrical to each other, so that the semiconductor stack 120 has a symmetrical structure, as shown in FIG. 16. On the other hand, as shown therein, the drain electrode 150d may be continuously disposed on the lower surface of the semiconductor stack 120 having the symmetrical structure.

Next, operation of the transistor according to this embodiment will be described.

First, upon application of positive voltage to the gate electrodes 150g, channels are formed in the third gallium nitride semiconductor layer 127 below the gate electrodes 150g. As a result, a voltage difference is created between the source electrodes 150s and the drain electrode 150d and causes migration of carriers (electrons) from the source electrodes 150s to the drain electrode 150d. Here, the carriers migrate from the first gallium nitride semiconductor layer 125 to the second gallium nitride semiconductor layer 129 through the channels below the gate electrodes 150g, spread to the plurality of second channel layers 130b by the current spreading layer 150a, and then move to the drain electrode 150d through the 2DEG regions formed in the second channel layers 130b.

As such, according to the present embodiment, it is possible to move the carriers at high velocity using 2DEG.

In this embodiment, the structure 130 is not limited to the superlattice structure and may have a multilayer structure in which the first channel layers 130a and the second channel layers 130b are stacked plural times.

Although many components are described above, it should be understood that the present invention does not essentially include all of these components. For example, the current spreading layer 150a, the first insulation layer 145b or the second insulation layer 145c may be omitted from the transistor according to the present invention. In addition, the number of first channel layers 130a and the number of second channel layers 130b are not particularly limited.

FIG. 17 is a schematic sectional view of a gallium nitride transistor according to a seventh embodiment of the present invention.

Referring to FIG. 17, although the transistor according to this embodiment is generally similar to the transistor described with reference to FIG. 16, a semiconductor stack 120a according to this embodiment includes a single first channel layer 130a. That is, the gallium nitride transistor of FIG. 16 includes the superlattice structure 130, which includes the plurality of first channel layers 130a, whereas the semiconductor stack 120a according to this embodiment includes a single first channel layer 130a.

The first channel layers 130a are formed of a gallium nitride semiconductor having a different energy band-gap from that of the high resistance gallium nitride semiconductor layer 129. For example, the first channel layers 130a may be formed of AlGaN. A 2DEG region is formed near an interface between the high resistance gallium nitride semiconductor layer 129 and each of the first channel layers 130a by the first channel layer 130a.

A drain electrode 150d may be connected to the 2DEG region. To this end, the drain electrode 150d may adjoin the high resistance gallium nitride semiconductor layer 129 and the first channel layer 130a.

On the other hand, gate electrodes 150g, a gate insulation layer 145a, source electrodes 150s, a current spreading layer 150a, a first insulation layer 145b, and a second insulation layer 145b are similar to those of the transistor described in FIG. 16, and detailed descriptions thereof will be omitted to avoid repeated descriptions.

FIG. 18 is a schematic sectional view of a gallium nitride transistor according to an eighth embodiment of the present invention.

Referring to FIG. 18, although the transistor according to this embodiment is generally similar to the transistor described with reference to FIG. 16, a lower surface of a semiconductor stack 120b according to this embodiment includes a non-contact region that does not adjoin the drain electrode 150d.

Particularly, in the lower surface of the semiconductor stack 120, at least some lower region of the source electrode 150s does not adjoin the drain electrode 150d. In addition, a lower surface of the semiconductor stack 120, on which a symmetrical center of the 2DEG regions is placed, does not contact the drain electrode 150d.

As shown in FIG. 18, the semiconductor stack 120 may include first dislocation defect areas TD1 in which dislocations are concentrated under the source electrodes 150s, and a second dislocation defect area TD2 in which dislocations are concentrated under the current spreading layer 150a. These dislocation defect areas TD1, TD2 provide paths through which carriers migrate directly from the source electrodes 150s to the drain electrode 150d, thereby causing current leakage.

Accordingly, the drain electrode 150d is formed so as not to adjoin the dislocation defect areas TD1, TD2, thereby securing high withstand voltage characteristics by prevention of current leakage.

On the other hand, a first current blocking layer 151 may adjoin the lower surface of the semiconductor stack 120 under the lower regions of the source electrodes 150s, and a second current blocking layer 153 may adjoin the lower surface of the semiconductor stack 120 at the symmetrical center of the 2DEG regions. These first and second current blocking layers 151, 153 block direct migration of carriers through the semiconductor stack 120 between the source electrode 150s and the drain electrode 150d.

According to this embodiment, the first dislocation defect areas TD1 and the second dislocation defect area TD2 are prevented from adjoining the drain electrode 150d, thereby providing a transistor having high withstand voltage characteristics.

FIG. 19 is a schematic sectional view of a gallium nitride transistor according to a ninth embodiment of the present invention.

Referring to FIG. 19, although the gallium nitride transistor according to this embodiment is generally similar to the gallium nitride transistor described with reference to FIG. 18, the semiconductor stack 120b according to this embodiment includes recesses 125a and a third current blocking layer 145d is placed within the recesses 125a.

The recesses 125a may penetrate a first conductive type first gallium nitride semiconductor layer 125 and expose a third gallium nitride semiconductor layer 127 or a second gallium nitride semiconductor layer 128. The recesses 125a may be formed by dry etching and/or wet etching an upper surface of the gallium nitride semiconductor stack 120b. The recesses 125a have a flat bottom surface. The stripes 123a as shown in FIG. 16 may be removed by formation of the recesses 125a.

On the other hand, at least some of source electrodes 160s may be connected to the first gallium nitride semiconductor layer 125 within the recesses 125a. In addition, the source electrodes 160s may be connected to the third gallium nitride semiconductor layer 127 within the recesses 125a.

A third current blocking layer 145d is placed between the source electrodes 150s and the semiconductor stack 120b. In particular, the third current blocking layer 145d is placed under the source electrode 160s and covers first dislocation defect areas TD1.

According to this embodiment, the transistor includes the third current blocking layer 145d together with the recesses 125a penetrating the first gallium nitride semiconductor layer 125, whereby migration of carriers from the source electrodes 160s to the first dislocation defect areas TD1 is blocked, thereby further enhancing withstand voltage characteristics.

Although the third current blocking layer 145d is formed together with the first current blocking layer 151 and the second current blocking layer 153 in this embodiment, the first current blocking layer 151 and/or the third current blocking layer 153 may be omitted. Thus, the drain electrode 150d may adjoin the lower surface of the semiconductor stack 120b under the source electrodes 160s.

FIG. 20 is a schematic sectional view of a gallium nitride transistor according to a tenth embodiment of the present invention.

Referring to FIG. 20, although the gallium nitride transistor according to this embodiment is generally similar to the gallium nitride transistor described with reference to FIG. 19, a semiconductor stack 120c according to this embodiment includes recesses 127a.

Specifically, the recesses 127a are formed on an upper surface of the semiconductor stack 120c. The recesses 127a may be formed by wet etching or dry etching and wet etching an exposed surface of the third gallium nitride semiconductor layer 127. The recesses 127a may be formed together with recesses 125a or may be formed independent of the recesses 125a.

As the exposed portion of the third gallium nitride semiconductor layer 127 is removed, it is possible to remove charge trap sites including an etching damage layer, impurities, and the like, which can remain in channel areas below gate electrodes 170g.

A gate insulation layer 145a covers the third gallium nitride semiconductor layer 127 within the recesses 127a, and the gate electrodes 170g may be disposed on the gate insulation layer 145a within the recesses 127a.

The recesses 127a, the gate insulation layer 145a and the gate electrodes 170g according to this embodiment may also be applied to the gallium nitride transistor described with reference to FIG. 16 and FIG. 17.

FIG. 21 to FIG. 28 are sectional views illustrating a method for manufacturing the gallium nitride transistor according to the eighth embodiment.

Referring to FIG. 21, a gallium nitride semiconductor layer 123 is grown on a growth substrate 121. The growth substrate 121 may be any substrate capable of growing the gallium nitride semiconductor layer 123 thereon, and may include, for example, a c-face sapphire substrate on which c-face GaN may be grown.

The semiconductor layer 123 and gallium nitride semiconductor layers described below may be grown by MOCVD or MBE. The semiconductor layer 123 may include a nucleus layer (not shown). The semiconductor layer 123 may be formed of, for example, GaN, and has a c-face growth plane.

Referring to FIG. 22, stripes 123a are formed by patterning the semiconductor layer 123. Patterning of the semiconductor layer 123 may be performed by photolithography and etching using a photoresist. In the course of patterning the semiconductor layer 123, the growth substrate 121 may also be partially removed to form protrusions 121a under the stripes 123a.

As shown, the stripes 123a may have inclined side surfaces. However, it should be understood that the present invention is not limited thereto and the side surfaces of the stripes may be perpendicular to the surface of the substrate 121.

Referring to FIG. 23, a first conductive type first gallium nitride semiconductor layer 125, a third gallium nitride semiconductor layer 127, a first conductive type second gallium nitride semiconductor layer 128, and a high resistance gallium nitride semiconductor layer 129 are grown on the stripes 123a.

The first conductive type first gallium nitride semiconductor layer 125 is grown on upper and side surfaces of the stripes 123a; the third gallium nitride semiconductor layer 127 is grown on upper and side surfaces of the first conductive type first gallium nitride semiconductor layer 125; and the first conductive type second gallium nitride semiconductor layer 128 is grown on upper and side surfaces of the third gallium nitride semiconductor layer 127. Further, the high resistance gallium nitride semiconductor layer 129 is grown on upper and side surfaces of the second gallium nitride semiconductor layer 128.

The upper surfaces of the semiconductor layers 125, 127, 128, 129 are c-faces and grown in a direction of [0001], and become Ga-faces. On the other hand, the side surfaces of the semiconductor layers semiconductor layers 125, 127, 128, 129 are grown in a direction of [11-22] or [1-101] and become (11-22) or (1-101) faces. The lateral directions of the semiconductor layers 125, 127, 129 are determined depending upon a longitudinal direction of the stripes 123a. For example, when the stripes 123a have a longitudinal direction of <1-100>, the side surface of the stripes becomes a (11-22) face, and when the stripes 123a have a longitudinal direction of <11-20>, the side surface of the stripes becomes a (1-101) face. The (11-22) face and the (1-101) face are semi-polar faces.

Growth rates of the upper and side surfaces of each of the semiconductor layers 125, 127, 128, 129 may be controlled by adjusting growth conditions, particularly, growth temperature and/or flux of each of source gases therefor. Accordingly, a vertical thickness of each of the semiconductor layers 125, 127, 128, 129 may be controlled to be the same as or different from a lateral thickness thereof. Particularly, as shown in FIG. 23, the vertical thickness of the third gallium nitride semiconductor layer 127 may be greater than the lateral thickness thereof.

On the other hand, since dislocations are transferred in an upward direction from the stripes 123a, first dislocation defect areas TD1 are formed on upper surfaces of the stripes 123a, whereas regions in the lateral direction of the stripes have a very low dislocation density.

As shown in FIG. 23, the first to third gallium nitride semiconductor layers 125, 127, 128 and the high resistance gallium nitride semiconductor layer 129 grown on the respective stripes 123a may be separated from one another. The first gallium nitride semiconductor layer 125 and the second gallium nitride semiconductor layer 128 may be formed of an n-type semiconductor, for example, n-type GaN, and the third gallium nitride semiconductor layer 127 may be formed of a p-type semiconductor, for example, p-type GaN, or may be formed of a semiconductor layer having a wider band-gap than the band-gap of the first and second gallium nitride semiconductor layers 125, 128, for example, i-type AlGaN. The p-type GaN requires a process for activating p-type impurities such as Mg and the like, whereas the i-type AlGaN does not requires activation of impurities, thereby simplifying the manufacturing process.

Referring to FIG. 24, a superlattice structure 130 is grown by alternately stacking first channel layers 130a and second channel layers 130b on the high resistance gallium nitride semiconductor layer 129.

The first channel layers 130a are formed of a gallium nitride semiconductor, for example, AlGaN, which has a different energy band-gap from those of the high resistance gallium nitride semiconductor layer 129 and the second channel layers 130b. The second channel layers 130b may be formed of, for example, GaN. In this case, 2DEG regions are formed in the second channel layers 130b having a relatively low energy band-gap.

On the other hand, as growth of the superlattice structure 130 continues, the superlattice structures 130 grown on adjacent stripes 123a may be connected to each other. Here, lots of dislocations are created in an intermediate region between the stripes 123a, that is, in a region where the superlattice structures 130 grown on the adjacent stripes 123a meet each other, thereby forming a second dislocation defect area TD2.

The number of first channel layers 130a and the number of second channel layers 130b in the superlattice structure 130 are not particularly limited. In addition, although the present embodiment includes the superlattice structure 130, it should be understood that the present invention is not limited to the superlattice structure, and the structure may have a multilayer structure in which first channel layers and second channel layers are alternately stacked one above another.

A planarization layer 131 is grown on the superlattice structure 130 to fill a groove formed on an upper surface of the superlattice structure 130. The planarization layer 131 may be grown as a gallium nitride semiconductor layer, for example, a GaN layer.

Referring to FIG. 25, the superlattice structure 130 is exposed by partially etching the planarization layer 131. The superlattice structure 130 may also be partially removed, and the planarization layer 131a remains in the groove formed in the superlattice structure 130.

By partial removal of the superlattice structure 130, some of the first channel layers 30a and some of the second channel layers 30b are exposed to the outside. As a result, the 2DEG regions formed on the second channel layers 130b are also exposed.

Referring to FIG. 26, a support substrate 141 is then attached to the upper surface of the superlattice structure 130. The support substrate 141 may be bonded to a metal layer 135 of Al or Ni/Ti/Au formed on the superlattice structure 130 and the planarization layer 131a via a bonding metal. Alternatively, the support substrate 141 may be formed on the metal layer 135 by plating. The support substrate 141 may include a ceramic or semiconductor substrate such as an AlN or AlSi substrate, or a metal substrate including Cu, Mo and/or W. Alternatively, the support substrate 141 may be integrally formed with the metal layer 135.

In addition, as shown therein, the metal layer 135 may be formed so as not to contact the first dislocation defect areas TD1 and the second dislocation defect area TD2, and current blocking layers 151, 153 may be formed on these regions.

The metal layer 135 may be connected to the first channel layers 130a and the second channel layers 130b, and thus may also be connected to the 2DEG regions.

Referring to FIG. 27, the growth substrate 121 is separated from the semiconductor layers. The growth substrate 121 may be separated from the semiconductor layers including the stripes 123a by, for example, laser lift-off.

In the course of separating the growth substrate 121 by laser lift-off, the exposed surfaces of the semiconductor layers can be damaged by laser beams, and Ga droplets can remain thereon. Thus, the exposed surfaces of the semiconductor layers are entirely recessed by wet etching or dry etching and wet etching, thereby removing the damaged surface or the Ga droplets. Dry etching may be carried out by reactive ion etching (RIE) and wet etching may be carried out using a KOH, NaOH or H₃PO₄ solution.

As a result, a final semiconductor stack 120 is obtained. On the other hand, when the third gallium nitride semiconductor layer 127 is a p-type semiconductor layer, the third gallium nitride semiconductor layer 127 may be activated by heat treatment at about 400° C. to about 950° C. in a N₂ or air atmosphere after separation of the growth substrate 121. The third gallium nitride semiconductor layer 127 may be activated before separation of the growth substrate 121. Since a space is present between the growth substrate 121 and the second conductive type gallium nitride semiconductor layer 127, the third gallium nitride semiconductor layer 127 may be activated by heat treatment at a temperature of, for example, about 900° C. in a N₂ or air atmosphere for about 60 minutes.

Referring to FIG. 28, an insulation layer 145 is deposited on the semiconductor stack 120. The insulation layer 145 may be formed of, for example, silicon oxide or silicon nitride, without being limited thereto.

Then, a gate insulation layer, 145a, a first insulation layer 145b and a second insulation layer 145c may be formed by patterning the insulation layer 145 through photolithography and etching, as shown in FIG. 16. The first insulation layer 145b may be formed on the stripes 123a and the second insulation layer 145c may be formed on the planarization layer 131a.

Next, source electrodes 150s connected to the first conductive type first gallium nitride semiconductor layer 125, gate electrodes 150g disposed on the gate insulation layer 145a, and a current spreading layer 150a are formed, thereby providing a gallium nitride transistor, as shown in FIG. 18. Here, a metal layer 135 is used as the drain electrode 150d.

In this embodiment, the metal layer 135 is formed so as not to adjoin the first dislocation defect areas TD1 and the second dislocation defect area TD2. Particularly, the metal layer 135 does not adjoin the first dislocation defect areas TD1 below the source electrodes 150s, thereby preventing current leakage. Alternatively, the metal layer 135 may be formed to adjoin the entirety of a lower surface of the semiconductor stack 120, thereby providing a gallium nitride transistor, as shown in FIG. 16.

In this embodiment, the superlattice structure 130 is formed on the high resistance gallium nitride semiconductor layer 129. Alternatively, a single first channel layer 130a may be formed thereon instead of the superlattice structure 130, thereby providing a gallium nitride transistor, as shown in FIG. 17.

FIG. 29 and FIG. 30 are sectional views illustrating a method for manufacturing the gallium nitride transistor according to the tenth embodiment of the invention.

Referring to FIG. 29, the growth substrate is separated through processes described with reference to FIG. 21 to FIG. 27. After separation of the growth substrate 121, an exposed surface of the semiconductor layers may be subjected to wet etching or dry etching and wet etching.

Then, as shown in FIG. 29, recesses 125a are formed to penetrate the first conductive type gallium nitride semiconductor layer 125. The recesses 125a may penetrate the third gallium nitride semiconductor layer 127 and the first conductive type second gallium nitride semiconductor layer 128 may be exposed through the recesses. The recesses 125a may be formed by plasma dry etching and may have a flat bottom surface. The recesses 125a may be formed by dry etching and/or wet etching.

On the other hand, the recesses 127a may be formed by wet etching using a KOH, NaOH or H₃PO₄ solution or by dry etching and wet etching an exposed surface of the third gallium nitride semiconductor layer 127. The recesses 127a may be formed together with recesses 125a or may be formed independent of the recesses 125a. As a result, a final semiconductor stack 120c having the recesses 125a, 127a is completed.

On the other hand, when the third gallium nitride semiconductor layer 127 is doped with p-type impurities, the third gallium nitride semiconductor layer 127 may be activated after formation of the recesses 125a.

In this embodiment, the third gallium nitride semiconductor layer 127 is activated after formation of the recesses 125a. However, it should be understood that the present invention is not limited thereto and the third gallium nitride semiconductor layer 127 may be activated after separation of the growth substrate 121 and before formation of the recesses 125a, or activated before separation of the growth substrate 121, as described with reference to FIG. 27.

Here, as activation of the third gallium nitride semiconductor layer is performed after formation of the recesses 125a, hydrogen can be extracted from the third gallium nitride semiconductor layer 127 through the recesses 125a, thereby promoting activation of the third gallium nitride semiconductor layer 127.

Referring to FIG. 30, then, a gate insulation layer 145a and a second insulation layer 145c are formed, and a current blocking layer 145d is formed within the recesses 127a. Then, source electrodes 160s, gate electrodes 170g, and a current spreading layer 150a are formed, thereby providing a gallium nitride transistor, as shown in FIG. 20. Here, a metal layer 135 is used as the drain electrode 150d.

The source electrodes 160s are connected not only to the first gallium nitride semiconductor layer 125, but also to the third gallium nitride semiconductor layer 127 through the recesses 125a.

According to this embodiment, the current blocking layer 145d is formed on the bottoms of the recesses 125a, thereby preventing current leakage through the first dislocation defect areas TD1 between the source electrodes 160s and the drain electrode 135; 50d.

According to this embodiment, the N-face of the semiconductor stack 120 is exposed to the outside by separation of the growth substrate 121. Unlike the Ga face, the N-face of the gallium nitride semiconductor layer can be easily etched by wet etching. Accordingly, patterning of the semiconductor stack can be achieved without etching damage, which is provided in the course of etching the Ga-face, thereby providing a gallium nitride transistor without etching damage. In particular, the recesses 127a are formed by wet etching, whereby carrier trap sites caused by plasma damage can be easily removed from the surface of the third gallium nitride semiconductor layer 127 below the gate electrodes 170g.

Although the recesses 127 are formed in this embodiment, formation of the recesses 127a may be omitted, thereby providing the gallium nitride transistor as shown in FIG. 19.

FIG. 31 is a schematic sectional view of a gallium nitride transistor according to a ninth embodiment of the present invention.

Referring to FIG. 31, the nitride transistor includes a semiconductor stack 230, a first regrowth layer 249, a second regrowth layer 251, source electrodes 253, gate electrodes 255, and a drain electrode 263. Further, the nitride transistor may include a gate insulation layer 245 and a substrate 271.

The semiconductor stack 230 includes a first nitride semiconductor layer 225, a channel layer 227 and a second nitride semiconductor layer 229, and may further include a contact layer 231. The channel layer 227 is disposed between the first nitride semiconductor layer 225 and the second nitride semiconductor layer 229, and may have a different conductive type than that of the first nitride semiconductor layer 225 and the second nitride semiconductor layer 229. For example, the first and second nitride semiconductor layers 225, 227 are n-type, and the channel layer 227 is p-type. Here, the “nitride semiconductor” may be an AlInGaN semiconductor and may include a binary, tertiary or quaternary semiconductor.

The first and second nitride semiconductor layers 225, 229 may be nitride semiconductor layers having the same composition, for example, GaN layers, but are not limited thereto. The first nitride semiconductor layer 225 may be formed of a nitride semiconductor doped with n-type impurities, for example, Si. On the other hand, the second nitride semiconductor layer 229 may be composed of a single layer, without being limited thereto. Alternatively, the second nitride semiconductor layer may include a nitride semiconductor layer disposed near the channel layer 227 and doped at a higher density than other portions thereof.

The channel layer 227 may be formed of a nitride semiconductor having the same composition as that of the first nitride semiconductor layer 225, without being limited thereto. For example, the channel layer 227 may be formed of a nitride semiconductor having a wider band-gap than the first nitride semiconductor layer 225. With this structure, the transistor may be turned on and off using an energy barrier of the channel layer 227.

The contact layer 231 is placed at the lowermost side of the semiconductor stack 230 and adjoins the drain electrode 263. The contact layer 231 may be formed of an n-type nitride semiconductor.

The semiconductor stack 230 has inclined surfaces 230a extending from an upper surface thereof to a lower surface thereof. As shown, the inclined surfaces 230a extend from the first nitride semiconductor layer 225 to the contact layer 231. The inclined surfaces 230a may be inclined at an angle of 20 to 70 degrees with respect to a lower surface of the semiconductor stack 230. For example, a reversed trapezoidal groove is formed in the semiconductor stack 230, thereby providing the inclined surfaces 230a at both sides of the semiconductor stack, as shown therein. The inclined surfaces 230a are preferably polar faces or semi-polar faces. The inclined surfaces 230a may be formed by wet etching the N-face of the nitride semiconductor layer and thus include wet-etched surfaces. In this case, the upper surface of the semiconductor stack 230 includes the N-face and the inclined surfaces 230a are the semi-polar faces.

A first regrowth layer 249 is disposed on some regions of the inclined surfaces 230a. The first regrowth layer 249 is formed by regrowth of a nitride semiconductor layer on some regions of the inclined surfaces 230a after forming the inclined surfaces 230a.

The first regrowth layer 249 has a different composition from that of a nitride semiconductor layer, for example, a second nitride semiconductor layer 229, disposed under the first regrowth layers. For example, the first regrowth layer 249 may be formed of a nitride semiconductor having a lower lattice parameter, such as AlGaN, than the second nitride semiconductor layer 229, or formed of a nitride semiconductor having a higher lattice parameter, such as InGaN, than the second nitride semiconductor layer 229.

A second regrowth layer 251 is formed on the first regrowth layer 249. As shown, the second regrowth layer 251 may be formed thereon such that the groove formed in the semiconductor stack 230 is filled with the second regrowth layer. The second regrowth layer 251 is formed of a nitride semiconductor having a different composition from that of the first regrowth layer 249, and may have the same or similar composition to the composition of the second nitride semiconductor layer 229.

As shown in FIG. 31, 2DEG regions are formed between the first regrowth layer 249 and the semiconductor stack 230. Alternatively, the 2DEG regions may be formed between the first regrowth layer 249 and the second regrowth layer 251. Locations of the 2DEG regions may be controlled depending upon the composition ratios, growth directions, and the like of the semiconductor stack 230, the first regrowth layer 249 and the second regrowth layer 251. The 2DEG regions extend from the upper surface of the semiconductor stack 230 to the lower surface thereof along the inclined surfaces 249, and may be connected to the drain electrode 263.

The source electrodes 253 are electrically connected to the first nitride semiconductor layer 225. The source electrodes 253 are formed of a conductive material capable of forming ohmic contact with the first nitride semiconductor layer. Furthermore, the source electrodes 253 may also be electrically connected to the channel layer 227.

The gate electrodes 255 are disposed to form channels between the first nitride semiconductor layer 225 and the first regrowth layer 249. As shown in FIG. 31, the gate electrodes 255 are disposed above some regions of the inclined surfaces 230a so as to form the channels, particularly, in the channel layer 227. In addition, a gate insulation layer 245 is disposed between the gate electrode 255 and the semiconductor stack 230. The gate insulation layer 245 may be formed of, for example, silicon oxide or silicon nitride, without being limited thereto.

The drain electrode 263 is connected to the lower surface of the semiconductor stack 230. As shown, the drain electrode 263 may be connected to the contact layer 231 and may also be connected to the first regrowth layer 249. In addition, the drain electrode 263 may be connected to the second regrowth layer 251. With this structure, the drain electrode 263 may be directly connected to the 2DEG regions. The drain electrode 263 may be composed of, for example, a metal layer, such as an Al or Ni/Ti/Au layer, and may be disposed between the support substrate 271 and the semiconductor stack 230. The support substrate 271 may be a conductive or insulating substrate. For example, the support substrate 271 may be formed of various materials such as AlN, AlSi, Cu or the like.

As shown, a pair of source electrodes 253 may be disposed symmetrical to each other and a pair of gate electrodes 255 may be disposed symmetrical to each other. To this end, the semiconductor stack 230 may have a symmetrical structure, as shown in FIG. 31. On the other hand, as shown therein, the drain electrode 263 may be continuously disposed on the lower surface of the semiconductor stack 230 having the symmetrical structure. Alternatively, although not shown, the drain electrode 263 may be disposed only in some area of the lower surface of the semiconductor stack 230.

Next, operation of the transistor according to this embodiment will be described.

First, upon application of positive voltage to the gate electrode 255, channels are formed in the channel layer 227 below the gate electrodes 255. As a result, a voltage difference is created between the source electrodes 253 and the drain electrode 263 and causes migration of carriers (electrons) from the source electrodes 253 to the drain electrode 263. Here, the carriers migrate from the first nitride semiconductor layer 225 to the second nitride semiconductor layer 229 through the channels below the gate electrodes 255, and then are moved from the second nitride semiconductor layer 229 to the drain electrode 263 through the 2DEG regions.

As such, according to the present embodiment, it is possible to move the carriers at high velocity using 2DEG.

In this embodiment, a distance between the drain electrode 263 and the channel layer 227 may be adjusted by thickness adjustment of the second nitride semiconductor layer 229, such that the withstand voltage of the transistor is controlled based on the distance. Accordingly, unlike a lateral type nitride transistor, the transistor according to this embodiment may have enhanced withstand voltage characteristics by increasing the height of the transistor instead of the area thereof, thereby enabling reduction in size (area) of the transistor.

FIG. 32 to FIG. 40 are sectional views illustrating a method for manufacturing the nitride transistor according to the ninth embodiment of the invention.

Referring to FIG. 32, a plurality of semiconductor layers including a first nitride semiconductor layer 225, a channel layer 227, and a second nitride semiconductor layer 229 are grown on a growth substrate 221. The plurality of semiconductor layers may include, for example, a buffer layer 223, and may include a contact layer 231.

The growth substrate 221 may be any substrate capable of growing a nitride semiconductor layer thereon and may include, for example, a c-face sapphire substrate on which c-face GaN may be grown.

The semiconductor layers may be grown by MOCVD or MBE. The buffer layer 223 may include a nucleus layer (not shown) and may be formed of, for example, GaN. The first nitride semiconductor layer 225 may be formed of a nitride semiconductor doped with n-type impurities, for example, Si, and may be formed of a binary, tertiary or quaternary semiconductor, such as an AlInGaN semiconductor.

The channel layer 227 may be formed of a nitride semiconductor having a different conductive type from that of the first nitride semiconductor layer 225. The channel layer 227 may be formed of a nitride semiconductor having the same composition as that of the first nitride semiconductor layer 225, without being limited thereto. For example, the channel layer 227 may be formed of a nitride semiconductor having a wider band-gap than the first nitride semiconductor layer 225.

The second nitride semiconductor layer 229 includes a high resistance semiconductor layer. In addition, the second nitride semiconductor layer 229 may include a nitride semiconductor layer (not shown) placed near the channel layer 227 and doped at a higher density than other portions thereof.

The contact layer 231 is formed of a nitride semiconductor doped with a higher density of impurities than the second nitride semiconductor layer 229.

Referring to FIG. 33, a first support substrate 241 is attached to an upper surface of a plurality of semiconductor layers. The first support substrate 241 may be attached to the semiconductor layers via a bonding layer 233. The bonding layer 233 may be formed of a heat resistant adhesive such as CeramaBond 865 and the like, or a metal having a high melting point such as molybdenum (Mo).

Referring to FIG. 34, first, the growth substrate 221 is separated from the semiconductor layers. The buffer layer 223 may also be removed together with the growth substrate 221. The growth substrate 221 may be separated from the semiconductor layers by, for example, laser lift-off.

In the course of separating the growth substrate 221 by laser lift-off, the exposed surfaces of the semiconductor layers can damaged by laser beams, and the exposed surfaces of the semiconductor layers may be entirely recessed by wet etching or dry etching and wet etching. As a result, the damaged surface or remaining materials on the surfaced exposed by laser lift-off can be removed. Dry etching may be carried out by reactive ion etching (RIE) and wet etching may be carried out using a KOH, NaOH or H₃PO₄ solution.

The first nitride semiconductor layer 225 is exposed by separation of the growth substrate 221. Then, a mask pattern 243 is formed on the exposed first nitride semiconductor layer 225, and the semiconductor layers 225, 227, 229, 231 are etched by wet etching or by dry etching and wet etching. The mask pattern 243 may be formed using a photoresist, and the wet etching may be performed using a KOH, NaOH or H₃PO₄ solution. The wet etching may be performed at a solution temperature of 100° C. in order to increase etching rate, and may be formed at a temperature of 200° C. or less in order to prevent damage to the mask pattern.

The nitride semiconductor layers are etched along crystal planes thereof by wet etching, whereby a groove is formed in the semiconductor stack 230. At both sides of the groove, inclined surfaces 230a are formed at an angle of, for example, 20 to 70 degrees with respect to the lower surface of the semiconductor stack 230. The inclined surfaces 230a extend from the upper surface of the semiconductor stack 230, that is, an upper surface of the first nitride semiconductor layer 225, to the lower surface of the semiconductor stack 230, for example, a lower surface of the contact layer 231. Further, wet etching may be stopped at the bonding layer 233, without being limited thereto. Alternatively, the bonding layer 233 may also be etched to expose a portion of the first support substrate 241.

After formation of the inclined surface 230a, the mask pattern 243 is removed. On the other hand, when the channel layer 227 is composed of a p-type nitride semiconductor layer, the channel layer 227 may be activated by heat treatment at about 400° C. to about 950° C. in a N₂ or air atmosphere. The channel layer 227 may also be activated directly using a N[[2]]₂ atmosphere after completion of growth in the growth chamber.

Referring to FIG. 35 and FIG. 36, an insulation layer 245 is formed on the semiconductor stack 230 and subjected to patterning through photolithography and etching to expose some regions of the inclined surfaces 230a. As a result, the insulation layer 245 covers the upper surface of the semiconductor stack 230 while partially covering the inclined surfaces 230a.

The insulation layer 245 may be formed of silicon oxide or silicon nitride. In addition, a mask pattern 247 may be formed to expose the insulation layer 345 within the groove for patterning of the insulation layer 245. The mask pattern 247 may be formed using a photoresist.

The insulation layer 245 within the groove may be etched using the mask pattern 247 as an etching mask. The insulation layer 245 may be etched by wet etching, whereby some regions of the inclined surfaces 230a are exposed. Then, the mask pattern 247 is removed.

Referring to FIG. 37, a first regrowth layer 249 is formed on some exposed regions of the inclined surfaces 230a. The first regrowth layer 249 is formed of a nitride semiconductor having a different composition from that of the second nitride semiconductor layer 229, and particularly, may have a different band-gap and lattice parameter from those of the second nitride semiconductor layer 229. For example, the first regrowth layer 249 and may be formed of a binary, tertiary or quaternary semiconductor, such as an AlInGaN semiconductor. For example, the first regrowth layer may be formed of, for example, InGaN or AlGaN.

A buffer layer (not shown) having the same composition as that of the second nitride semiconductor layer 229 may be grown before growth of the first regrowth layer 249.

Then, a second regrowth layer 251 is formed on the first regrowth layer 249. The second regrowth layer 251 is formed of a nitride semiconductor having a different composition from that of the first regrowth layer 249. For example, the second regrowth layer 251 may have the same composition as that of the second nitride semiconductor layer 229.

Growth of the first regrowth layer 249 and the second regrowth layer 251 is restricted by the insulation layer 245. On the other hand, the second regrowth layer 251 may partially fill the groove in the semiconductor stack 230, as shown in FIG. 37.

A 2DEG region may be formed at an interface between the first regrowth layer 249 and the second nitride semiconductor layer 229 due to differences in band-gap and lattice parameter therebetween, or at an interface between the first regrowth layer 249 and the second regrowth layer 251 due to differences in band-gap and lattice parameter therebetween.

Referring to FIG. 38, openings are formed to expose an upper surface of the semiconductor stack 230 by patterning the insulation layer 245 through photolithography and etching. Then, the first nitride semiconductor layer 225 may be partially removed through the openings to expose the channel layer 227.

Then, source electrodes 253 are formed to be connected to the first nitride semiconductor layer 225. In addition, gate electrodes 255 are formed on the insulation layer 245 of the inclined surfaces 230a. The source electrodes 253 are connected to the first nitride semiconductor layer 225 and to the channel layer 227 through the openings of the insulation layer 245. On the other hand, the gate electrodes 255 are formed on the insulation layer 245 to be adjacent to side surfaces of the channel layer 227 to form channels in the channel layer 227 exposed to the inclined surfaces 230a.

In this embodiment, the insulation layer 245 may act as a gate insulation layer. Alternatively, the insulation layer 245 may be removed before formation of the source electrodes 253 and the gate electrodes 255, and the gate insulation layer may be formed again to cover the channel layer 227 of the inclined surfaces 230a.

Referring to FIG. 39, the first support substrate 241 is separated from the semiconductor stack 230. For separation of the first support substrate 241, a second support substrate 261 may be attached to the semiconductor stack 230 via fillers 257. The second support substrate 261 supports the semiconductor stack 230 during separation of the first support substrate 241.

As the first support substrate 241 is separated, the lower surface of the semiconductor stack 230, for example, the lower surface of the contact layer 231, is exposed.

Referring to FIG. 40, a drain electrode 263 is formed on the lower surface of the semiconductor stack 230. The drain electrode 263 adjoins the contact layer 231, and may also adjoin the first regrowth layer 249 and the second regrowth layer 251. As a result, the 2DEG regions may be connected to the drain electrode 263. The drain electrode 263 may be formed of a metal layer such as an Al or Ni/Ti/Au layer.

Then, a third support substrate 271 is attached to a lower side of the drain electrode 263. The third support substrate 271 may be bonded to the drain electrode 263 via a bonding meal (not shown). Alternatively, the support substrate 271 may be formed on the drain electrode 263 by plating. The support substrate 271 may include a ceramic or semiconductor substrate such as an AlN or AlSi substrate, or a metal substrate including Cu, Mo and/or W.

Then, the fillers 257 and the second support substrate 261 are removed from the semiconductor stack 230, thereby providing the nitride transistor as shown in FIG. 31.

FIG. 41 is a schematic block diagram of a hybrid transistor according to embodiments of the present invention.

Referring to FIG. 41, the hybrid transistor includes a switching element 310, a channel element 320 and a connector 330, and may include a substrate 340.

The switching element 310 is a transistor having a switching function, such as MOSFET, HFET, and the like, and may include, for example, a Si-based MOSFET or a GaAs/AlGaAS or InP/InGaAs-based HFET.

The channel element 320 includes a stack of gallium nitride semiconductor layers. In particular, a 2DEG region may be formed by piezoelectric polarization by stacking gallium nitride semiconductor layers having different lattice parameters. Furthermore, the channel element 320 may form a plurality of 2DEG regions, thereby enabling rapid flow of large current.

The connector 330 electrically connects the switching element 310 to the channel element 320. The switching element 310 and the channel element 320 are connected in series between a source electrode S and a drain electrode D, and are disposed on a common substrate 340.

The substrate 340 may be a growth substrate for growing the gallium nitride semiconductor layers of the channel element 320, without being limited thereto.

In the embodiments, the switching element 310 has a switching function of the hybrid transistor. The switching element 310 may include a source electrode, a drain electrode and a gate electrode, and is turned on or turned off by gate voltage.

On the other hand, when the switching element 310 is turned on, the channel element 320 provides a channel through which electrons migrate to the drain electrode D. When the switching element 310 is turned off, current flow through the channel element 320 is blocked. Resistance of the channel element 320 may be adjusted according to a length of the channel element. The channel element 320 is formed to have higher resistance than the switching element 310 when turned off. For example, in a turn-off state, resistance of the channel element 320 is 10 times or more than the resistance of the switching element 310. With this structure, the hybrid transistor can exhibit high withstand voltage characteristics.

FIG. 42 is a schematic sectional view of a hybrid transistor according to a tenth embodiment of the present invention

Referring to FIG. 42, the hybrid transistor includes a switching element 310, a channel element 320, and a connector 331, and may include a substrate 341.

The switching element 310 may be a general HFET. For example, the switching element 310 may include a substrate 311, a channel layer 313 and a barrier layer 315, and may include a source electrode 317S, a gate electrode 317G and a drain electrode 317D. Here, the source electrode 317S corresponds to a source electrode S of the hybrid transistor. In addition, the switching element 310 may be a GaAs/AlGaAs, InP/InGaAs or GaN/AlGaN HFET having a normally off structure. Particularly, the GaAs/AlGaAs HFET allows rapid switching operation and is thus more preferred.

The channel element 320 includes a stack formed by alternately stacking gallium nitride semiconductor layers having different lattice parameters, for example, first semiconductor layers 323 and second semiconductor layers 325. A 2DEG region is formed at an interface between the first semiconductor layer 323 and the second semiconductor layer 325 by a difference in band-gap therebetween, spontaneous polarization and piezoelectric polarization. A plurality of 2DEG regions is formed by repeatedly stacking the first semiconductor layers 323 and the second semiconductor layers 325. The first semiconductor layers 323 and the second semiconductor layers 325 may be formed of AlInGaN semiconductors having different compositions, and may be formed of, for example, GaN and AlGaN, respectively. Particularly, the first semiconductor layer 323 and the second semiconductor layer 325 may be undoped layers.

On the other hand, a first electrode 327a is connected to one side of the stack 320 and a second electrode 327D is connected to the other side of the stack 320. The first electrode 327a may be formed of, for example, Ni/Au, and the second electrode 327D may be formed of, for example, Ti/Al. Here, the second electrode 327D corresponds to a drain D of the hybrid transistor.

As described above in FIG. 41, turn-off resistance of the channel element 320 may be adjusted by adjusting the length L of the channel element 320, that is, a distance between the first electrode 327a and the second electrode 327D.

The connector 331 connects the drain electrode 317D of the switching element 310 to the first electrode 327a of the channel element 320. The connector 331 may be, for example, a bonding wire, without being limited thereto.

The substrate 341 may be a growth substrate for growing the gallium nitride semiconductor layers 323, 325 of the channel element 320. For example, the substrate 341 may include a Si substrate, an insulating SiC substrate, an insulating GaN substrate, a spinel substrate, a sapphire substrate, and the like. Accordingly, the semiconductor layers 323, 325 are attached to an upper surface of the substrate 341 without separate adhesives. The switching element 310 is attached to the upper surface of the substrate 341 by bonding.

When the switching element 310 is turned on by voltage applied to the gate electrode 317G, electrons migrate from the source electrode 317S to the second electrode 327D. On the other hand, when the switching element 310 is turned off, the channel element 320 undergoes voltage drop due to rapid increase in resistance of the channel element 320, whereby small voltage is applied between the source electrode 317S and the drain electrode 317D of the switching element 310. Accordingly, the withstand voltage characteristics of the hybrid transistor may be enhanced by adjusting the structure and length L of the channel element 320, and the switching element 310 may be formed to a relatively very small size since there is no need for consideration of withstand voltage in design of the switching element.

FIG. 43 is a schematic sectional view of a hybrid transistor according to an eleventh embodiment of the present invention.

Referring to FIG. 43, although the hybrid transistor according to this embodiment is generally similar to the hybrid transistor described with reference to FIG. 42, a switching element 310 of the hybrid transistor according to this embodiment is disposed at a different location.

Specifically, in the hybrid transistor of FIG. 42, the switching element 310 is disposed parallel to the channel element 320 on the substrate 341. On the contrary, in this embodiment, the switching element 310 is disposed on the channel element 320.

With the structure of the switching element 310 disposed on the channel element 320, it is possible to reduce an area occupied by the hybrid transistor.

FIG. 44 is a schematic sectional view of a hybrid transistor according to a twelfth embodiment of the present invention.

Referring to FIG. 44, although the hybrid transistor according to this embodiment is generally similar to the hybrid transistor described with reference to FIG. 42, a switching element 310 of the hybrid transistor according to this embodiment is a MOSFET instead of the HFET of FIG. 42.

Specifically, in this embodiment, the switching element 310 is a MOSFET which employs a source region 342 and a drain region 343 formed by implantation of impurities, instead of an HFET having a heterogeneous structure. The switching element 310 may be a Si-based MOSFET, without being limited thereto. Due to high reliability, the Si-based MOSFET has been used in the art for several decades. Accordingly, it is possible to provide a reliable hybrid transistor using the Si-based MOSFET as the switching element 310. On the other hand, although the Si-based MOSFET used as the switching element 310 provides a disadvantage in terms of rapid switching operation as compared with the HFET switching element 310, a carrier migration distance of the switching element 310 is negligibly smaller than that of the channel element 320 and thus does not significantly obstruct rapid switching operation of the hybrid transistor.

On the other hand, the Si-based MOSFET may be fabricated using a Si substrate 351. In addition, the gallium nitride semiconductor layers 323, 325 of the channel element 320 may be grown on the Si substrate 351.

The hybrid transistor according to this embodiment may be formed on the substrate 351 through the following process.

First, gallium nitride semiconductor layers 323, 325 are grown on the substrate 351. Then, an upper surface of the substrate 351 is exposed by removing other portions excluding a region of the channel element 320 through photolithograph and etching. Next, impurities are implanted to form a source region 342, a drain region 343, and a gate insulation layer 345. Thereafter, a gate electrode 347G, a source electrode 347S and a drain electrode 347D are formed, and a first electrode 327a and a second electrode 327D are formed. The drain electrode 347D and the first electrode 327a of the switching element 310 are electrically connected to each other. Here, a connector 33 may be formed by wiring, or may be formed together with the drain electrode 347D or the first electrode 327a.

FIG. 45 is a schematic sectional view of a hybrid transistor according to a thirteenth embodiment of the present invention.

Referring to FIG. 45, although the hybrid transistor according to this embodiment is generally similar to the hybrid transistor described with reference to FIG. 42, a channel element 320 of the hybrid transistor according to this embodiment is fabricated independent of a substrate 361 and then mounted on the substrate 361.

Specifically, the channel element 320 is grown and fabricated as a separate element on a growth substrate 321, and mounted together with a switching element 310 on a common substrate 361. The substrate 361 may include bonding pads 363, and a first electrode 327a and a second electrode 327D of the channel element 320 may be bonded to the bonding pad 363.

The drain electrode 317D of the switching element 310 may be electrically connected to the bonding pad 363, to which the first electrode 327a is bonded, through a connector 331.

Although various embodiments have been described above, it should be understood that some features of a certain embodiment may also be applied to other embodiments in the same or similar ways without departing from the spirit and scope of the present invention. Power devices may be provided using various group III-V based transistors, particularly, the gallium nitride transistors described above.

1. A group III-V based transistor comprising:
a semiconductor stack having an upper surface and a lower surface opposite to the upper surface, the semiconductor stack comprising a III-V based semiconductor layer; and
at least one 2DEG region extending from the upper surface of the semiconductor stack to the lower surface thereof.

2. The group III-V based transistor according to claim 1, further comprising:
a source electrode disposed on the upper surface of the semiconductor stack and connected to a first III-V based semiconductor layer;
a gate electrode disposed between the first III-V based semiconductor layer and the 2DEG region to form a channel therebetween; and
a drain electrode disposed on the lower surface of the semiconductor stack.

3. The group III-V based transistor according to claim 2, further comprising
a support substrate,
wherein the drain electrode is disposed between the support substrate and the semiconductor stack.

4. The group III-V based transistor according to claim 2, wherein the drain electrode is connected to the 2DEG region.

5. The group III-V based transistor according to claim 2, further comprising:
an insulation layer disposed within a region between the source electrode and the first III-V based semiconductor layer.

6. The group III-V based transistor according to claim 2, further comprising:
a current spreading layer disposed on an upper surface of the semiconductor stack and connected to the 2DEG region.

7. The group III-V based transistor according to claim 6, further comprising:
an insulation layer disposed within a region between the current spreading layer and the semiconductor stack.

8. The group III-V based transistor according to claim 1, wherein the semiconductor stack comprises:
a first conductivity-type first group III-V based semiconductor layer having an upper surface, a lower surface opposite to the upper surface, and a side surface;
a first conductivity-type second group III-V based semiconductor layer surrounding the lower surface and the side surface of the first conductivity-type first group III-V based semiconductor layer;
a second conductivity-type group III-V based semiconductor layer disposed between the first group III-V based semiconductor layer and the second group III-V based semiconductor layer and separating the first group III-V based semiconductor layer and the second group III-V based semiconductor layer from each other; and
at least one channel layer disposed near a side surface of the first conductivity-type second group III-V based semiconductor layer and comprising a 2DEG region.

9. The group III-V based transistor according to claim 8, further comprising:
a source electrode;
a drain electrode; and
a gate electrode,
wherein
the source electrode is electrically connected to the first conductivity-type group III-V based semiconductor layer;
the gate electrode being disposed to form a channel in the second conductivity-type group III-V based semiconductor layer; and
the drain electrode being disposed on a lower surface of the semiconductor stack.

10. The group III-V based transistor according to claim 9, wherein the source electrode is also electrically connected to the second conductivity-type group III-V based semiconductor layer.

11. The group III-V based transistor according to claim 10, wherein;
the first conductivity-type group III-V based semiconductor layer comprises a recess exposing the second conductivity-type group III-V based semiconductor layer; and
the source electrode is electrically connected to the second conductivity-type group III-V based semiconductor layer through the recess.

12. The group III-V based transistor according to claim 8, wherein:
the semiconductor stack comprises a gallium nitride semiconductor layer; and
the upper surface of the first conductivity-type first group III-V based semiconductor layer comprises an N-face.

13. The group III-V based transistor according to claim 12, wherein at least one of the first conductivity-type first group III-V based semiconductor layer, the second conductive type III-V based semiconductor layer, and the first conductive type second III-V based semiconductor layer comprises an etched face formed by wet etching.

14. The group III-V based transistor according to claim 8, wherein the semiconductor stack comprises a gallium nitride semiconductor layer, and the side surface of the first conductivity-type group III-V based semiconductor layer comprises a (11-22) face or a (1-101) face.

15. The group III-V based transistor according to claim 8, wherein the group III-V based transistor comprises:
first channel layers comprising AlInGaN semiconductor layers; and
second channel layers each being disposed between the first channel layers and comprising AlInGaN semiconductor layers.

16. The group III-V based transistor according to claim 15, wherein the first channel layers and the second channel layers comprise a superlattice structure.

17. The group III-V based transistor according to claim 15, wherein the first channel layers comprise AlGaN and the second channel layers comprise GaN.

18. The group III-V based transistor according to claim 1, wherein the semiconductor stack comprises a gallium nitride semiconductor layer and an upper surface of the semiconductor stack comprises an N-face.

19. The group III-V based transistor according to claim 18, wherein the semiconductor stack comprises an etched N-face.

20. The group III-V based transistor according to claim 19, wherein the semiconductor stack comprises a recess disposed on an upper surface thereof.

21. A group III-V based transistor, comprising:
a semiconductor stack having an upper surface and a lower surface opposite to the upper surface, the semiconductor stack comprising a gallium nitride semiconductor layer as a group III-V based semiconductor layer;
a source electrode electrically connected to the semiconductor stack;
a drain electrode electrically connected to the semiconductor stack; and
a gate electrode forming a channel between the source electrode and the drain electrode,
wherein:
the upper surface of the semiconductor stack comprises an N-face;
the semiconductor stack comprises at least one recess formed by wet etching or by wet etching after dry etching; and
at least a portion of the source electrode, the gate electrode, is disposed on the recess.

22. The group III-V based transistor according to claim 21, further comprising:
a support substrate disposed on the lower surface of the semiconductor stack,
wherein the drain electrode is disposed between the support substrate and the semiconductor stack.

23. The group III-V based transistor according to claim 21, further comprising:
a gate insulation layer disposed between the gate electrode and the semiconductor stack.

24. A method for manufacturing a group III-V based transistor, comprising:
forming a stripe of a group III-V based semiconductor on a growth substrate;
growing group III-V based semiconductor layers on the stripe, the group III-V based semiconductor layers being grown in an upward direction and in a lateral direction of the stripe;
attaching a support substrate to the group III-V based semiconductor layers; and
separating the growth substrate from the semiconductor layers.

25. The method for manufacturing a group III-V based transistor according to claim 24, wherein growing the semiconductor layers comprises:
growing a first conductivity-type group III-V based semiconductor layer on the stripe;
growing a second conductivity-type group III-V based semiconductor layer on the first conductivity-type group III-V based semiconductor layer;
growing a first conductivity-type group second group III-V based semiconductor layer on the second conductivity-type group III-V based semiconductor layer; and
growing at least group III-V channel layer on the second group III-V based semiconductor layer to form a 2DEG region.

26. The method for manufacturing a group III-V based transistor according to claim 25, further comprising:
activating impurities of the second conductivity-type group III-V based semiconductor layer,
wherein the first conductivity-type group is n-type and the second conductivity-type is p-type.

27. The method for manufacturing a group III-V based transistor according to claim 25, comprising:
alternately growing group III-V-based first channel layers and group III-V-based second channel layers on the first conductivity-type second group III-V based semiconductor layer.

28. The method for manufacturing a group III-V based transistor according to claim 25, further comprising:
partially removing an upper surface of the semiconductor layers to expose at least one 2DEG region before attaching the support substrate.

29. The method for manufacturing a group III-V based transistor according to claim 24, wherein separation of the growth substrate comprises separating the growth substrate from the semiconductor layers using laser lift-off, and wet etching the exposed semiconductor layers.

30. The method for manufacturing a group III-V based transistor according to claim 29, further comprising:
forming a recess on the exposed semiconductor layers by wet etching the exposed semiconductor layers.

31-33. (canceled)
